(19) United States
(12) Patent Application Publication
(10) Pub. No.: US 2025/0392280 A1
(43) Pub. Date: Dec. 25, 2025

(54) FILTER CIRCUIT AND FILTER DEVICE

(71) Applicant: Murata Manufacturing Co., Ltd., Nagaokakyo-shi, Kyoto-fu (JP)

(72) Inventor: Keisuke OGAWA, Nagaokakyo-shi (JP)

(21) Appl. No.: 19/312,588

(22) Filed: Aug. 28, 2025

Related U.S. Application Data
(63) Continuation of application No. PCT/JP2024/015439, filed on Apr. 18, 2024.

(30) Foreign Application Priority Data
May 30, 2023 (JP) 2023-088794

(51) Int. Cl. H03H 7/01; H01F 27/28; H01G 4/30

(52) U.S. Cl. CPC H03H 7/0115; H01F 27/2804; H01G 4/30; H01F 2027/2809

(57) ABSTRACT

A filter device includes first and second terminals, a ground terminal, a first resonator connected to the first and second terminals, and a third resonator connected to the second terminal. A second resonator is coupled with the first and third resonators. The first and third resonators are magnetically and capacitively coupled with each other. The first resonator includes a first inductor and a first capacitor connected in parallel between the first terminal and the ground terminal. The third resonator includes a second inductor and a second capacitor connected in parallel between the second terminal and the ground terminal. The second resonator includes a third inductor including first and second end portions, a third capacitor including a first end connected to the first end portion of the third inductor, and a fourth capacitor including a first end connected to the second end portion of the third inductor.

### CROSS REFERENCE TO RELATED APPLICATIONS

This application claims the benefit of priority to Japanese Patent Application No. 2023-088794 filed on May 30, 2023 and is a Continuation Application of PCT Application No. PCT/JP2024/015439 filed on Apr. 18, 2024. The entire contents of each application are hereby incorporated herein by reference.

### BACKGROUND OF THE INVENTION

### 1. Field of the Invention

The present disclosure relates to filter circuits and filter devices, and particularly to techniques for improving attenuation characteristics of band pass filters.

### 2. Description of the Related Art

International Publication No. 2022/071191 discloses a band pass filter that includes four LC resonators. In the band pass filter disclosed in International Publication No. 2022/071191, the four resonators are disposed in a dielectric multilayer body in series in a direction from an input terminal to an output terminal and are disposed so as to form a substantially C-shaped signal path from the input terminal to the output terminal.

The band pass filter is required to generate attenuation poles in a higher frequency region and a lower frequency region than a preferred frequency path band. In the case where the band pass filter includes multiple resonators that include inductors and capacitors as disclosed in International Publication No. 2022/071191, coupling between resonators bypassing a resonator series path from the input terminal to the output terminal, that is, “cross coupling” enables the attenuation poles to be generated.

The number of the attenuation poles that are generated due to the “cross coupling” is determined depending on a difference in the number of the resonators between a main path on which a signal is transmitted via all of the resonators and a sub path on which a signal is transmitted across some of the resonators. For this reason, four or more tiers of resonators are needed to generate two attenuation poles due to the cross coupling.

In some cases, the band pass filter is used for small communication devices such as a cellular phone and a smartphone, but these devices are required to be downsized and thinned, and it is necessary to reduce the size of the band pass filter itself accordingly.

A conceivable method of reducing the size of the band pass filter is to reduce the number of the resonators that are included in the filter. In the case where the number of the resonators is less than 4, however, the difference in the number of the resonators regarding the cross coupling is 1, and accordingly, the attenuation poles cannot be generated in both sides of a pass band by using the cross coupling.

### SUMMARY OF THE INVENTION

Example embodiments of the present invention provide filter circuits that each include three resonators, generate attenuation poles in both sides of a pass band, and define and function as a band pass filter.

A filter circuit according to an example embodiment of the present invention includes a first terminal, a second terminal, a ground terminal, a first resonator connected to the first terminal, a second resonator, and a third resonator connected to the second terminal. The second resonator is coupled with the first resonator and the third resonator. The first resonator and the third resonator are magnetically coupled with each other and capacitively coupled with each other. The first resonator includes a first inductor and a first capacitor connected in parallel between the first terminal and the ground terminal. The third resonator includes a second inductor and a second capacitor connected in parallel between the second terminal and the ground terminal. The second resonator includes a third inductor including a first end portion and a second end portion, a third capacitor including a first end connected to the first end portion of the third inductor, and a fourth capacitor including a first end connected to the second end portion of the third inductor.

A filter device according to another example embodiment of the present invention includes a multilayer body, an input terminal, an output terminal, a ground terminal connected to a ground terminal, first to seventh capacitor electrodes, first to third plate electrodes, and first to third vias. The multilayer body includes multiple stacked dielectric layers and a first surface and a second surface that face away from each other. The input terminal, the output terminal, and the ground terminal are disposed in or on the second surface of the multilayer body. The first capacitor electrode is connected to the input terminal and at least partially overlaps the ground electrode in plan view in a normal direction to the first surface. The first plate electrode is connected to the first capacitor electrode. The second capacitor electrode is connected to the output terminal and at least partially overlaps the ground electrode in plan view in the normal direction to the first surface. The second plate electrode is connected to the second capacitor electrode and is provided in the same dielectric layer as the first plate electrode. The first via is connected to the first plate electrode and the second plate electrode and is connected to the ground electrode. The third plate electrode is provided in the same dielectric layer as the first plate electrode and the second plate electrode and is magnetically coupled with the first plate electrode and the second plate electrode. The second via and the third via are connected to the third plate electrode. The third capacitor electrode is connected to the second via and at least partially overlaps the ground electrode in plan view in the normal direction to the first surface. The fourth capacitor electrode is connected to the third via and at least partially overlaps the ground electrode in plan view in the normal direction to the first surface. The fifth capacitor electrode at least partially overlaps the first capacitor electrode and the second capacitor electrode in plan view in the normal direction to the first surface. The sixth capacitor electrode at least partially overlaps the first capacitor electrode and the third capacitor electrode in plan view in the normal direction to the first surface. The seventh capacitor electrode at least partially overlaps the second capacitor electrode and the fourth capacitor electrode in plan view in the normal direction to the first surface.

A filter device according to another example embodiment of the present invention includes a multilayer body, an input terminal, an output terminal, a ground electrode, and first to sixth electrodes. The multilayer body includes multiple stacked dielectric layers and a first surface and a second surface that face away from each other. The input terminal, the output terminal, and the ground electrode are provided in or on the second surface of the multilayer body. The first electrode at least partially overlaps the ground electrode in plan view in a normal direction to the first surface and is connected to the input terminal. The second electrode at least partially overlaps the ground electrode in plan view in the normal direction to the first surface, is provided in the same dielectric layer as the first electrode, and is connected to the output terminal. The third electrode is adjacent to the first electrode and the second electrode and at least partially overlaps the ground electrode in plan view in the normal direction to the first surface. The fourth electrode connects the first electrode and the second electrode. The fifth electrode at least partially overlaps the first electrode and the third electrode in plan view in the normal direction to the first surface. The sixth electrode at least partially overlaps the second electrode and the third electrode in plan view in the normal direction to the first surface. The first electrode and the second electrode are spaced from each other, face each other, and include a capacitively coupled region.

With filter circuits according to example embodiments of the present invention, two resonators (a first resonator and a third resonator) that are connected to an input end and an output end are magnetically coupled with each other and capacitively coupled with each other, and a second resonator at an intermediate tier is a resonator of a “both-ends open type” in which capacitors are connected to both sides of an inductor. This structure enables each filter circuit that includes the three resonators to generate attenuation poles on both sides of a pass band and accordingly enables the filter circuits to each define and function as a band pass filter.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a block diagram of a communication device that includes a radio-frequency front-end circuit in which a filter device according to a first example embodiment of the present invention is used.

FIG. 2 is an equivalent circuit diagram of the filter device according to the first example embodiment of the present invention.

FIG. 3 is a perspective view of the filter device according to the first example embodiment of the present invention.

FIG. 4 is an exploded perspective view of an example of the multilayer structure of the filter device in FIG. 3.

FIG. 5 is a diagram for describing topologies regarding the filter device according to the first example embodiment and a filter device in a comparative example.

FIG. 6 is a first diagram for describing filter characteristics of the filter device according to the first example embodiment and the filter device in the comparative example.

FIG. 7 is a second diagram for describing the filter characteristics of the filter device according to the first example embodiment and the filter device in the comparative example.

FIG. 8 is an exploded perspective view of the multilayer structure of a filter device according to a first modification of an example embodiment of the present invention.

FIG. 9 is an equivalent circuit diagram of a filter device according to a second modification of an example embodiment of the present invention.

FIGS. 10A and 10B illustrate a plan view and a transparent side view of an example of the structure of the filter device in FIG. 9.

FIG. 11 is an equivalent circuit diagram of a filter device according to a third modification of an example embodiment of the present invention.

FIG. 12 is an exploded perspective view of an example of the multilayer structure of the filter device in FIG. 11.

FIG. 13 is an equivalent circuit diagram of a filter device according to a fourth modification of an example embodiment of the present invention.

FIG. 14 is an equivalent circuit diagram of a filter device according to a fifth modification of an example embodiment of the present invention.

FIG. 15 is an equivalent circuit diagram of a first example of a filter device according to a sixth modification of an example embodiment of the present invention.

FIG. 16 is an equivalent circuit diagram of a second example of the filter device according to the sixth modification.

FIG. 17 is an equivalent circuit diagram of a filter device according to a second example embodiment of the present invention.

FIG. 18 is an equivalent circuit diagram of a filter device according to a seventh modification of an example embodiment of the present invention.

FIG. 19 is an equivalent circuit diagram of a filter device according to an eighth modification of an example embodiment of the present invention.

FIG. 20 is an equivalent circuit diagram of a filter device according to a third example embodiment of the present invention.

FIG. 21 is an exploded perspective view of a first example of the multilayer structure of the filter device in FIG. 20.

FIG. 22 is an exploded perspective view of a second example of the multilayer structure of the filter device in FIG. 20.

FIG. 23 is an equivalent circuit diagram of a filter device according to a ninth modification of an example embodiment of the present invention.

### DETAILED DESCRIPTION OF THE EXAMPLE EMBODIMENTS

Example embodiments of the present invention will hereinafter be described in detail with reference to the drawings. In the drawings, portions the same as or corresponding to each other are designated by the same reference signs, and a description for these is not repeated.

### First Example Embodiment

### Basic Structure of Communication Device

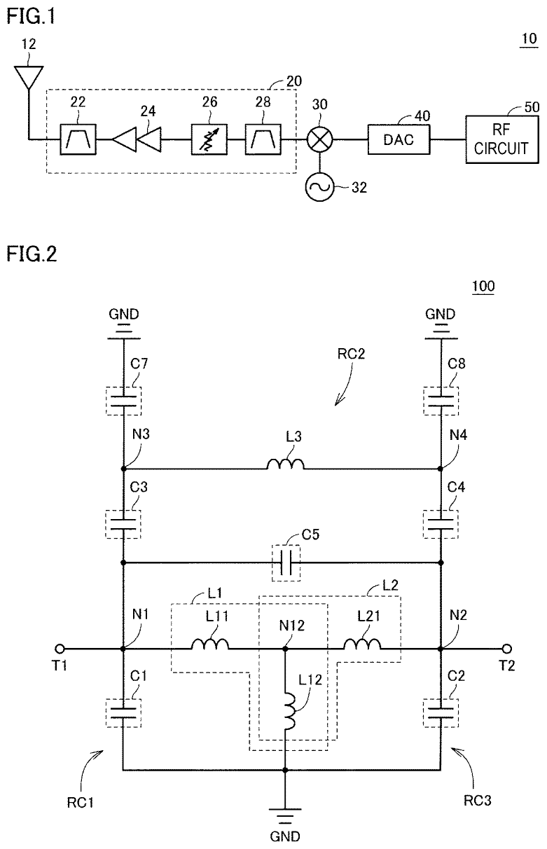

FIG. 1 is a block diagram of a communication device 10 that includes a radio-frequency front-end circuit 20 in which a filter device 100 according to a first example embodiment of the present invention is used. Examples of the communication device 10 include a mobile terminal represented by, for example, a smartphone or a cellular phone base station.

Referring to FIG. 1, the communication device 10 includes an antenna 12, the radio-frequency front-end circuit 20, a mixer 30, a local oscillator 32, a D/A convertor (DAC) 40, and an RF circuit 50. The radio-frequency front-end circuit 20 includes band pass filters 22 and 28, an amplifier 24, and an attenuator 26. In a case described below, the radio-frequency front-end circuit 20 includes a transmission circuit that transmits a radio-frequency signal from the antenna 12 in FIG. 1, but the radio-frequency front-end circuit 20 may include a reception circuit that receives a radio-frequency signal via the antenna 12.

The communication device 10 up-converts a transmission signal that is transmitted from the RF circuit 50 into a radio-frequency signal and emits the radio-frequency signal from the antenna 12. A modulated digital signal that is the transmission signal that is outputted from the RF circuit 50 is converted into an analog signal by using the D/A convertor 40. The mixer 30 mixes the transmission signal that is converted from the digital signal to the analog signal by using the D/A convertor 40 with an oscillation signal from the local oscillator 32 and up-converts the signal into a radio-frequency signal. The band pass filter 28 removes a spurious wave that is generated due to up-converting and extracts only a transmission signal in a preferred frequency band. The attenuator 26 adjusts the intensity of the transmission signal. The amplifier 24 is used for power amplification of the transmission signal that passes through the attenuator 26 into a predetermined level. The band pass filter 22 removes a spurious wave that is generated due to the amplification and permits only a signal component in a frequency band that is defined by a communication standard to pass. The transmission signal that passes through the band pass filter 22 is emitted from the antenna 12.

The filter device according to example embodiments of the present invention can be used for the band pass filters 22 and 28 in the communication device 10 described above.

### Structure of Filter Device

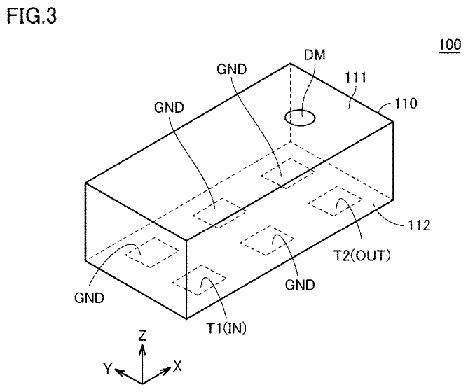

The structure of the filter device 100 according to the present example embodiment will now be described in detail with reference to FIG. 2 to FIG. 4. In the following description, a circuit that is disposed in the filter device 100 is also referred to as a “filter circuit”.

### (1) Equivalent Circuit

FIG. 2 is an equivalent circuit diagram of the filter device 100. Referring to FIG. 2, the filter device 100 includes an input terminal T1, an output terminal T2, ground terminals GND, resonators RC1 to RC3, and a capacitor C5. The resonators RC1 to RC3 are LC resonators that include inductors and capacitors.

The resonator RC1 is a LC parallel resonator that includes a capacitor C1 and an inductor L1 that are connected in parallel between the input terminal T1 and the ground terminal GND. The inductor L1 includes inductors L11 and L12 that are connected in series between the input terminal T1 and the ground terminal GND. The inductor L11 is connected to the input terminal T1, and the inductor L12 is connected between the inductor L11 and the ground terminal GND.

The resonator RC3 is a LC parallel resonator that includes a capacitor C2 and an inductor L2 that are connected in parallel between the output terminal T2 and the ground terminal GND. The inductor L2 includes inductors L21 and L12 that are connected in series between the input terminal T1 and the ground terminal GND. The inductor L21 is connected to the output terminal T2, and the inductor L12 is connected between the inductor L21 and the ground terminal GND.

In other words, the inductor L11 and the inductor L21 are connected in series between the input terminal T1 and the output terminal T2, and the inductor L12 is connected between a connection node N12 of the inductor L11 and the inductor L21 and the ground terminal GND. That is, the inductor L12 is shared by the resonator RC1 and the resonator RC3. With the structures of the inductors L1 and L2, the resonator RC1 and the resonator RC3 are magnetically coupled with each other.

The capacitor C5 is connected between a connection node N1 of the capacitor C1 and the inductor L1 in the resonator RC1 and a connection node N2 of the capacitor C2 and the inductor L2 in the resonator RC3. Electric field coupling occurs between the resonator RC1 and the resonator RC3 due to the capacitor C5.

A resonator RC2 includes an inductor L3 and capacitors C3 and C4 that are connected to both ends of the inductor L3. The capacitor C3 is connected between a first end of the inductor L3 and the connection node N1. The capacitor C4 is connected between a second end of the inductor L3 and the connection node N2. A capacitor C7 is connected between a connection node N3 of the inductor L3 and the capacitor C3 and the ground terminal GND, and a capacitor C8 is connected between a connection node N4 of the inductor L3 and the capacitor C4 and the ground terminal GND.

The resonator RC2 defines a LC resonator of a both-ends open type by using the inductor L3 and the capacitors C3 and C4. It can be seen that the LC resonator of the both-ends open type includes the capacitors C7 and C8 in addition to the inductor L3 and the capacitors C3 and C4.

The capacitor C3 connects the resonator RC1 and the resonator RC2 to each other, and the capacitor C4 connects the resonator RC2 and the resonator RC3 to each other. That is, the electric field coupling occurs between the resonator RC1 and the resonator RC2, and the electric field coupling occurs between the resonator RC2 and the resonator RC3.

As for the filter device 100, a path that extends from the input terminal T1 to the output terminal T2 includes a first path that extends from the resonator RC1 to the resonator RC3 via the resonator RC2 and a second path that extends from the resonator RC1 directly to the resonator RC3 across the resonator RC2. The “cross coupling” enables an attenuation pole to be generated as in the second path.

### (2) Specific Structure

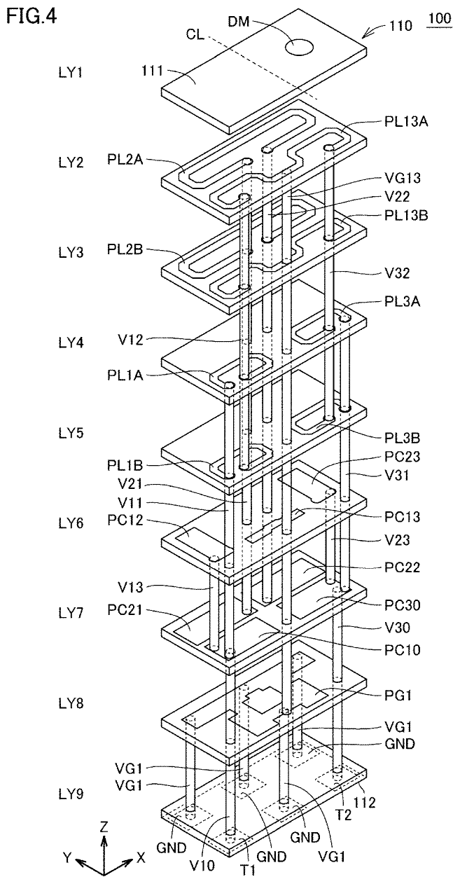

The structure of the filter device 100 will now be described with reference to FIG. 3 and FIG. 4. FIG. 3 is a perspective view of the filter device 100. FIG. 4 is an exploded perspective view of an example of the multilayer structure of the filter device 100.

Referring to FIG. 3 and FIG. 4, the filter device 100 includes a multilayer body 110 that has a rectangular cuboid shape or a substantially rectangular cuboid shape in which multiple dielectric layers LY1 to LY9 are stacked in a stacking direction. The dielectric layers LY1 to LY9 include ceramics such as, for example, low temperature co-fired ceramics (LTCC) or resin. In the multilayer body 110, inductors and capacitors of the LC resonator include multiple electrodes that are provided in the dielectric layers and multiple vias that are provided between the dielectric layers. In the present specification, the “vias” are conductors that are provided in the dielectric layers in order to connect the electrodes that are provided in the different dielectric layers. The vias include, for example, conductive paste, plating, and/or a metal pin.

In the description below, the stacking direction of the dielectric layers LY1 to LY9 in the multilayer body 110 is a “Z-axis direction”, a direction that is perpendicular or substantially perpendicular to the Z-axis direction and that is parallel or substantially parallel with a first side of each layer in the multilayer body is an “X-axis direction”, a direction that is parallel or substantially parallel with a second side of each layer in the multilayer body is a “Y-axis direction”. In some cases below, a positive Z-axis direction in the figures is an upward direction, and a negative Z-axis direction is a downward direction. In FIG. 4, a long side of each dielectric layer that has a rectangular or substantially rectangular shape is the first side, and a short side is the second side.

A directional mark DM for identifying the direction of the filter device 100 is disposed on an upper surface 111 (the dielectric layer LY1: a first surface) of the multilayer body 110. External terminals (the input terminal T1, the output terminal T2, and the multiple ground terminals GND) for connecting the filter device 100 and an external device to each other are disposed in or on a lower surface 112 (the dielectric layer LY9: the second surface) of the multilayer body 110. The input terminal T1, the output terminal T2, and the ground terminals GND are electrodes that have a plate shape and are LGA (Land Grid Array) terminals that are regularly disposed in or on the lower surface 112 of the multilayer body 110.

As described in FIG. 2, the filter device 100 includes the three resonators RC1 to RC3 that are LC resonators. More specifically, the resonator RC1 includes vias V10 to V12 and VG13, a capacitor electrode PC10, and plate electrodes PL1A, PL1B, PL13A, and PL13B. The resonator RC2 includes vias V21 and V22, capacitor electrodes PC12, PC21, PC22, and PC23, and plate electrodes PL2A and PL2B. The resonator RC3 includes vias V30 to V32, the via VG13, a capacitor electrode PC30, and the plate electrodes PL13A and PL13B. The via VG13 and the plate electrodes PL13A and PL13B are shared by the resonators RC1 and RC3.

The structure of the resonator RC1 will now be described. The input terminal T1 that is disposed in or on the lower surface 112 (the dielectric layer LY9) of the multilayer body 110 is connected to the capacitor electrode PC10 that is disposed in the dielectric layer LY7 by using the via V10. The capacitor electrode PC10 has a rectangular or substantially rectangular shape and at least partially overlaps a ground electrode PG1 that is disposed in the dielectric layer LY8 in plan view of the multilayer body 110 in the stacking direction (the Z-axis direction). The ground electrode PG1 is connected to the ground terminals GND that are disposed in or on the lower surface 112 by multiple vias VG1. That is, the capacitor electrode PC10 and the ground electrode PG1 define the capacitor C1 in FIG. 2. The capacitor electrode PC10 is connected to the plate electrode PL1A that is disposed in the dielectric layer LY4 and the plate electrode PL1B that is disposed in the dielectric layer LY5 by the via V11.

The plate electrodes PL1A and PL1B are belt-shaped electrodes that have an O-shaped or substantially O-shaped wiring pattern and have the same or substantially the same shape in plan view of the multilayer body 110 in the stacking direction. The via V11 is connected to first ends of the plate electrodes PL1A and PL1B, and the via V12 is connected to second ends thereof. The via V12 is connected to the plate electrode PL13A that is disposed in the dielectric layer LY2 and the plate electrode PL13B that is disposed in the dielectric layer LY3.

The plate electrodes PL13A and PL13B are belt-shaped electrodes that include a combination of C-shaped wiring patterns and have the same or substantially the same shape in plan view of the multilayer body 110 in the stacking direction. The plate electrodes PL13A and PL13B have line symmetry with respect to an imaginary line CL that passes through the center of the X-axis and that is parallel or substantially parallel with the Y-axis in plan view of the multilayer body 110 in the stacking direction. The via V12 is connected to first ends of the plate electrodes PL13A and PL13B, and the via V32 is connected to second ends thereof. The via VG13 is connected to central portions along the paths of the plate electrodes PL13A and PL13B. The via VG13 is connected to the ground electrode PG1 that is disposed in the dielectric layer LY8.

That is, a path from a connection point of the via V12 to a connection point of the via VG13 in the vias V10 to V12, the plate electrodes PL1A and PL1B, and the plate electrodes PL13A and PL13B defines the inductor L11 in FIG. 2. The via VG13 defines the inductor L12 in FIG. 2.

The structure of the resonator RC3 will now be described. The output terminal T2 that is disposed in or on the lower surface 112 of the multilayer body 110 is connected to the capacitor electrode PC30 that is disposed in the dielectric layer LY7 by the via V30. The capacitor electrode PC30 has a rectangular or substantially rectangular shape and is adjacent to the capacitor electrode PC10. The capacitor electrode PC30 at least partially overlaps the ground electrode PG1 that is disposed in the dielectric layer LY8 in plan view of the multilayer body 110 in the stacking direction. That is, the capacitor electrode PC30 and the ground electrode PG1 define the capacitor C2 in FIG. 2. The capacitor electrode PC30 is connected to a plate electrode PL3A that is disposed in the dielectric layer LY4 and a plate electrode PL3B that is disposed in the dielectric layer LY5 by the via V31.

The plate electrodes PL3A and PL3B are belt-shaped electrodes that have an O-shaped or substantially O-shaped wiring pattern and have the same or substantially the same shape in plan view of the multilayer body 110 in the stacking direction. The plate electrodes PL3A and PL3B exhibit line symmetry with the plate electrodes PL1A and PL1B. The via V31 is connected to first ends of the plate electrodes PL3A and PL3B, and the via V32 is connected to second ends thereof. The via V32 is connected to the plate electrode PL13A that is disposed in the dielectric layer LY2 and the plate electrode PL13B that is disposed in the dielectric layer LY3.

That is, a path from a connection point of the via V32 to a connection point of the via VG13 in the vias V30 to V32, the plate electrodes PL3A and PL3B, and the plate electrodes PL13A and PL13B defines the inductor L21 in FIG. 2. The via VG13 defines the inductor L12 in FIG. 2 as described above.

The capacitor electrode PC10 of the resonator RC1 and the capacitor electrode PC20 of the resonator RC2 partially overlap a capacitor electrode PC13 that are linearly disposed in the dielectric layer LY6 in plan view of the multilayer body 110 in the stacking direction. The capacitor electrodes PC10, PC13, and PC30 define the capacitor C5 in FIG. 2.

The resonator RC2 will now be described. In the dielectric layer LY7, the capacitor electrode PC21 and the capacitor electrode PC22 are adjacent in a positive Y-axis direction from the capacitor electrodes PC10 and PC30. The capacitor electrodes PC21 and PC22 have the same or substantially the same rectangular or substantially rectangular shape. The capacitor electrodes PC21 and PC22 at least partially overlap the ground electrode PG1 that is disposed in the dielectric layer LY8 in plan view of the multilayer body 110 in the stacking direction. That is, the capacitor electrode PC21 and the ground electrode PG1 define the capacitor C7 in FIG. 2. The capacitor electrode PC22 and the ground electrode PG1 define the capacitor C8 in FIG. 2.

The capacitor electrode PC21 partially overlaps the capacitor electrode PC12 that is disposed in the dielectric layer LY6 in plan view of the multilayer body 110 in the stacking direction. The capacitor electrode PC12 has a rectangular or substantially rectangular shape and is connected to the capacitor electrode PC10 of the resonator RC1 by using a via V13. That is, the capacitor electrode PC21 and the capacitor electrode PC12 define the capacitor C3 in FIG. 1.

Similarly, the capacitor electrode PC22 partially overlaps the capacitor electrode PC23 that is disposed in the dielectric layer LY6 in plan view of the multilayer body 110 in the stacking direction. The capacitor electrode PC23 has a rectangular or substantially rectangular shape and is connected to the capacitor electrode PC30 of the resonator RC3 by using a via V23. That is, the capacitor electrode PC22 and the capacitor electrode PC23 define the capacitor C4 in FIG. 1.

The capacitor electrode PC21 is connected to the plate electrode PL2A that is disposed in the dielectric layer LY2 and the plate electrode PL2B that is disposed in the dielectric layer LY3 by the via V21. The plate electrodes PL2A and PL2B are belt-shaped electrodes that have a C-shaped or substantially C-shaped wiring pattern and have the same or substantially the same shape in plan view of the multilayer body 110 in the stacking direction. The plate electrodes PL2A and PL2B have line symmetry with respect to the imaginary line CL in plan view of the multilayer body 110 in the stacking direction.

Portions of the plate electrodes PL2A and PL2B extend along the plate electrodes PL13A and PL13B that are included in the resonators RC1 and RC2. This arrangement causes the plate electrode PL2A and the plate electrode PL13A to be magnetically coupled with each other and causes the plate electrode PL2B and the plate electrode PL13B to be magnetically coupled with each other.

The via V12 is connected to first ends of the plate electrodes PL2A and PL2B, and the via V22 is disposed at second ends thereof. The via V22 is connected to the capacitor electrode PC22 that is disposed in the dielectric layer LY7. That is, the vias V21 and V22 and the plate electrodes PL2A and PL2B define the inductor L3 in FIG. 2.

As illustrated in FIG. 4, elements in the multilayer body 110 that are included in the filter device 100 have line symmetry with respect to the imaginary line CL as a whole.

A band pass filter is required to generate attenuation poles in a higher frequency region and a lower frequency region than a preferred frequency path band. A known method of generating the attenuation poles regarding a filter device that includes multiple resonators is to generate the attenuation poles by causing the “cross coupling” to occur such that a resonator series path from an input terminal to an output terminal is bypassed.

The number of the attenuation poles that are generated by the “cross coupling” is determined depending on a difference in the number of the resonators between a main path on which a signal is transmitted via all of the resonators and a sub path on which a signal is transmitted across some of the resonators. For this reason, four or more tiers of resonators are usually needed to generate two attenuation poles due to the cross coupling.

Such a band pass filter is used for small communication devices such as, for example, a cellular phone and a smartphone in some cases. As for each of these devices, the size and thickness thereof need to be reduced, and there is a need to reduce the size of the band pass filter itself accordingly. As for the band pass filter that includes the multiple resonators, the number of elements (plate electrodes and vias) that are included in inductors and capacitors of the resonators greatly affects the size. For this reason, the size of the band pass filter can be reduced by reducing the number of the resonators that are included in the filter. In the case where the attenuation poles are generated by using the cross coupling as described above, however, a filter that includes three resonators cannot generate the attenuation poles in both sides of the pass band by using the cross coupling because the difference in the number of the resonators regarding the cross coupling is 1.

As for the filter device according to the first example embodiment, each band pass filter includes different types of the resonators, and an aspect of coupling between the resonators is designed. Consequently, even the filter that includes the three resonators defines and functions as the band pass filter that has the attenuation poles in both sides of the pass band.

More specifically, as for the filter device according to the first example embodiment, a first-tier resonator that is connected to the input terminal and a second-tier resonator that is connected to the output terminal are magnetically coupled with each other, and the electric field coupling occurs therebetween. A resonator of the both-ends open type is used as the second-tier resonator, and consequently, coupling between the first-tier resonator and the second-tier resonator in the frequency path band differs from coupling between the second-tier resonator and a third-tier resonator. With this structure, the degree of coupling of the sub path between the input terminal and the third-tier resonator or the first-tier resonator and the output terminal can be higher than the degree of coupling of the sub path between the first-tier resonator and the third-tier resonator. As a result, the signal that passes through the main path and the signals that pass through the sub paths have the same or substantially the same amplitude and opposite phases in points on both sides of the preferred pass band, and the attenuation poles can be generated at the points. Accordingly, even the filter device that has a three-tier structure can define and function as the band pass filter that has the attenuation poles in both sides of the pass band.

FIG. 5 is a diagram for describing topologies illustrating the state of coupling between the resonators for the filter device 100 according to the first example embodiment and a filter device 100X that has a four-tier structure in a comparative example. In FIG. 5, the topology for the filter device 100 according to the first example embodiment is illustrated on the left-hand side, and the topology for the filter device 100X in the comparative example is illustrated on the right-hand side. In the topologies, “IN” and “OUT” nodes correspond to the input terminal and the output terminal, nodes designated by numerals correspond to the respective resonators. As for the state of coupling between the nodes, “+” represents the electric field coupling, and “−” represents magnetic coupling.

As for the filter device 100X in the comparative example, coupling between the resonators is the electric field coupling. In this case, the difference in the number of the resonators, through which the paths extend, between a main path from the first-tier resonator to the fourth-tier resonator via the second-tier and third-tier resonators and a sub path that is directly coupled with the fourth-tier resonator from the first-tier resonator is 2. This enables two or more attenuation poles to be generated regarding a symmetrical structure.

As for the filter device that has the three-tier structure as in the filter device 100 according to the first example embodiment, the cross coupling occurs between the first-tier and third-tier resonators. As for the filter device 100 according to the first example embodiment, a resonator of the both-ends open type that includes capacitors that are disposed at both ends of an inductor is used as the second-tier resonator. An electric field that is generated at the resonator of the both-ends open type is zero near the center of the resonator, and an end portion thereof has positive polarity (+), and another end portion thereof has negative polarity (−). Consequently, coupling between the first-tier and second-tier resonators and coupling between the second-tier and third-tier resonators differ from each other.

The electric field coupling and the magnetic coupling occur between the first-tier resonator and the third-tier resonator, and the degree of the cross coupling between the first-tier and third-tier resonators is reduced by the electric field coupling and the magnetic coupling on balance. Consequently, the degree of coupling between the input terminal and the third-tier resonator or the degree of coupling between the first-tier resonator and the output terminal is higher than the degree of coupling between the first-tier and third-tier resonators. Consequently, the signal that passes through the main path and the signal that passes through the sub path have the same amplitude and opposite phases at a point on both sides of the preferred pass band, and the attenuation pole can be generated at the point. Accordingly, the filter device that includes the three resonators can generate the attenuation poles in both sides of the pass band, and accordingly, the filter device can define and function as the band pass filter.

In order to reverse the polarity of coupling on a signal path, for example, the second-tier resonator can be a single-side grounded resonator as in the first-tier and third-tier resonators, an inductor can be used for the magnetic coupling between the first-tier and second-tier resonators, and a capacitor can be used for the electric field coupling between the second-tier and third-tier resonators. In this case, however, the arrangement of elements of the entire filter device is asymmetrical. In the case where the arrangement of elements is asymmetrical, variations in characteristics are likely to occur due to, for example, an arrangement error in a manufacturing process, and the typical values (Typ values) of the characteristics worsens.

As for the filter device according to the first example embodiment, the resonator of the both-ends open type is used as the second-tier resonator, and consequently, the polarity of coupling between the first-tier and second-tier resonators and the polarity of coupling between the second-tier and third-tier resonators can be opposite to each other on a main signal transmission path (the main path) even when the arrangement of the elements of the entire filter device is symmetrical.

### Comparison of Bandpass Characteristic

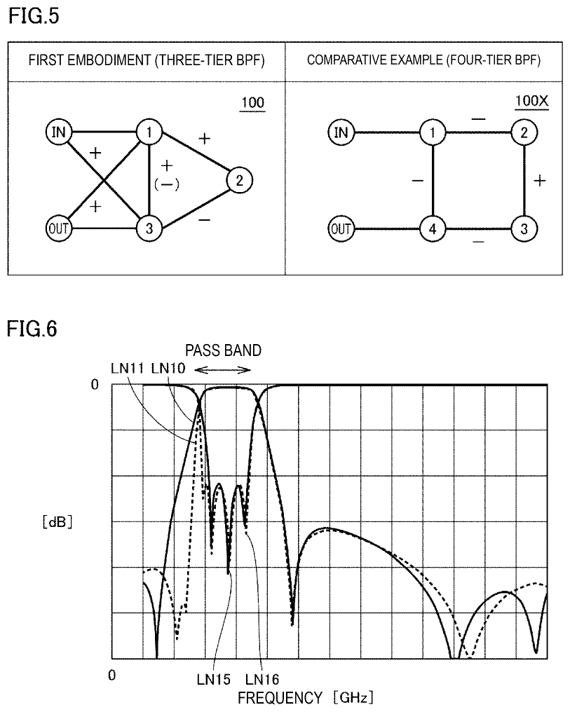

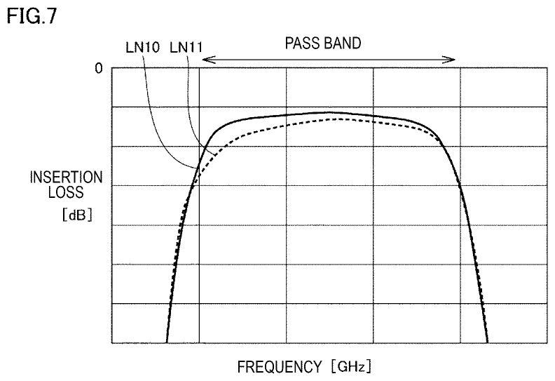

FIG. 6 and FIG. 7 are diagrams for describing filter characteristics of the filter device 100 according to the first example embodiment and the filter device 100X in the comparative example. In FIG. 6, the horizontal axis represents frequency, and the vertical axis represents the insertion loss and return loss of each filter device. FIG. 7 is an enlarged view of the insertion loss near the pass band in FIG. 6. In FIG. 6 and FIG. 7, solid lines LN10 and LN15 represent the insertion loss and return loss of the filter device 100 according to the first example embodiment, and dashed lines LN11 and LN16 represent the insertion loss and return loss of the filter device 100X in the comparative example.

As illustrated in FIG. 6, the filter device 100 according to the first example embodiment generates the attenuation poles on both sides of the pass band and can define and function as the band pass filter. In the case of the filter device 100 according to the first example embodiment (the solid line LN10), the number of the resonators is reduced, the attenuation pole in the lower frequency region than the pass band is consequently farther than that in the case of the filter device 100X in the comparative example that has the four-tier structure (the dashed line LN11) from the pass band, the steepness of the attenuation characteristics near the pass band slightly worsens. On the one hand, the attenuation characteristics have the same or substantially the same level as in the comparative example in the higher frequency region than the pass band. On the other hand, as illustrated in FIG. 7, the insertion loss of the filter device 100 according to the first example embodiment is improved in the pass band particularly in a low frequency region because the number of the resonators is reduced unlike the filter device 100X in the comparative example.

The filter device 100 according to the first example embodiment includes the three resonators, the resonator of the both-ends open type is used as the second-tier resonator, the cross coupling occurs between the first-tier resonator and the third-tier resonator by using the magnetic coupling and the electric field coupling, and consequently, the filter device can define and function as the band pass filter as described above. In addition, the elements in the multilayer body can be symmetrical, and variations in characteristics can be reduced.

The “connection node N1” and the “connection node N2” according to the first example embodiment correspond to a “first terminal” and a “second terminal”. The “resonator RC1”, the “resonator RC2”, and the “resonator RC3” according to the first example embodiment correspond to a “first resonator”, a “second resonator”, and a “third resonator”. The “capacitor C1” to the “capacitor C5”, the “capacitor C7”, and the “capacitor C8 according to the first example embodiment correspond to a “first capacitor” to a “fifth capacitor”, a “seventh capacitor” and an “eighth capacitor”. The “inductor L1” to the “inductor L3” according to the first example embodiment correspond to a “first inductor” to a “third inductor”.

The “capacitor electrode PC10”, the “capacitor electrode PC10”, the “capacitor electrode PC21”, the “capacitor electrode PC22”, the “capacitor electrode PC13”, the “capacitor electrode PC12”, and the “capacitor electrode PC23” according to the first example embodiment correspond to a “first capacitor electrode” to a “seventh capacitor electrode”. The “plate electrodes PL13A and PL13B” according to the first example embodiment correspond to a “first plate electrode” and a “second plate electrode”. The “plate electrodes PL2A and PL2B” according to the first example embodiment correspond to a “third plate electrode”. The “via VG13”, the “via V21”, and the “via V22” according to the first example embodiment correspond to a “first via” to a “third via”.

### First Modification

In the case described regarding the filter device 100 according to the first example embodiment, the resonators that are provided in the multilayer body 110 include the vias and the wiring patterns. In the case described according to a first modification, the equivalent circuit illustrated in FIG. 2 has a multilayer structure that differs from that in FIG. 4. According to a first modification of an example embodiment of the present invention, the resonators include wiring patterns without vias.

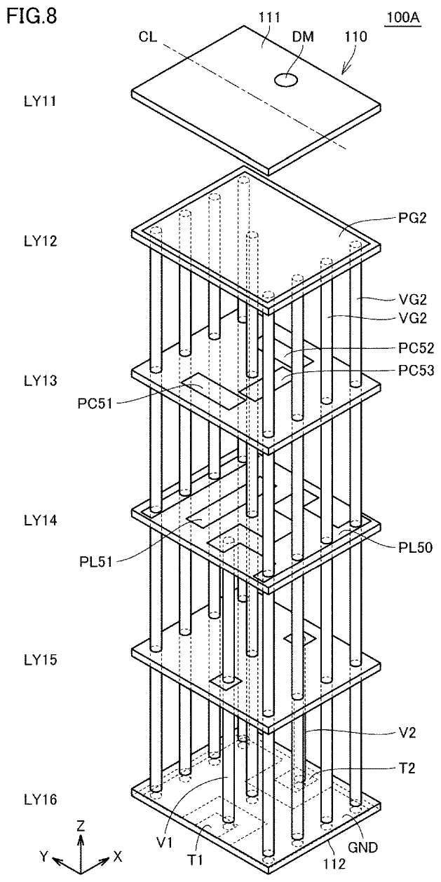

FIG. 8 is an exploded perspective view illustrating an example of the multilayer structure of a filter device 100A according to the first modification. The multilayer body 110 of the filter device 100A includes dielectric layers LY11 to LY16 that are stacked in the stacking direction (the Z-axis direction).

The directional mark DM to identify the direction of the filter device 100A is disposed on the upper surface 111 (the dielectric layer LY11: the first surface) of the multilayer body 110. The input terminal T1, the output terminal T2, and the ground terminal GND to connect the filter device 100A and an external device to each other are disposed in or on the lower surface 112 (the dielectric layer LY16: the second surface) of the multilayer body 110. The ground terminal GND is an H-shaped or substantially H-shaped plate electrode that is partially notched. The input terminal T1 is disposed at a portion of the dielectric layer LY16 that is notched in an X-axis negative direction. The input terminal T1 is disposed at a portion of the dielectric layer LY16 that is notched in an X-axis positive direction.

A ground electrode PG2 is disposed in the dielectric layer LY12 so as to cover the entire or substantially the entire surface of the dielectric layer. The ground electrode PG2 is connected to the ground terminal GND in the dielectric layer LY16 by using multiple vias VG2 that are located on the circumference of the multilayer body 110 along the side surfaces of the multilayer body 110.

The input terminal T1 that is disposed in or on the lower surface 112 of the multilayer body 110 is connected to the plate electrode PL50 that is disposed in the dielectric layer LY14 by using the via V1. The plate electrode PL50 is formed by connecting first ends of two L-shaped wiring patterns (a first electrode and a second electrode) to a rectangular or substantially rectangular shaped wiring pattern (a third electrode) that extends in the X-axis direction. The two L-shaped wiring patterns are line symmetric with respect to the imaginary line CL that passes through the center of the X-axis of the dielectric layer and that is parallel or substantially parallel with the Y-axis in plan view of the multilayer body 110 in the stacking direction.

The via V1 that is connected to the input terminal T1 is connected to the wiring pattern (the first electrode) of the L-shaped wiring patterns that is disposed in the X-axis negative direction. The output terminal T2 is disposed at the L-shaped wiring pattern (the second electrode) that is disposed in the X-axis positive direction via the via V2. The third electrode that connects the two L-shaped wiring patterns is connected to the ground electrode PG2 and the ground terminal GND by the vias VG2.

The plate electrode PL50 at least partially overlaps the ground electrode PG2 and the ground terminal GND in plan view of the multilayer body 110 in the stacking direction. The via V1 and the first electrode and the third electrode of the plate electrode PL50 define the inductor L1 in the resonator RC1 of the equivalent circuit in FIG. 2, and a capacitance component between this portion and the ground electrode PG2 and between this portion and the ground terminal GND defines the capacitor C1 in FIG. 2. Similarly, the via V2 and the second electrode and the third electrode of the plate electrode PL50 define the inductor L2 and the capacitor C2 in the resonator RC3 in FIG. 2.

In the dielectric layer LY14, a plate electrode PL51 is adjacent to the plate electrode PL50 along portions of the first electrode and the second electrode of the plate electrode PL50 that extend in the X-axis direction. An inductance component of the plate electrode PL51 defines the inductor L3 in FIG. 2. A capacitance component between the plate electrode PL51 and the ground electrode PG2 and between the plate electrode PL51 and the ground terminal GND defines the capacitors C7 and C8 in FIG. 2.

Capacitor electrodes PC51, PC52, and PC53 that have a rectangular or substantially rectangular shape are disposed in the dielectric layer LY13. The capacitor electrode PC51 partially overlaps the first electrode of the plate electrode PL50 and the plate electrode PL51 in plan view of the multilayer body 110 in the stacking direction. The plate electrodes PL50 and PL51 and the capacitor electrode PC51 define the capacitor C3 in FIG. 2. The capacitor electrode PC52 partially overlaps the second electrode of the plate electrode PL50 and the plate electrode PL51 in plan view of the multilayer body 110 in the stacking direction. The plate electrodes PL50 and PL51 and the capacitor electrode PC52 define the capacitor C4 in FIG. 2. That is, the plate electrode PL51 and the capacitor electrodes PC51 and PC52 define the resonator RC2 in FIG. 2.

The capacitor electrode PC53 partially overlaps the first electrode and the second electrode of the plate electrode PL50 in plan view of the multilayer body 110 in the stacking direction. The first electrode and the second electrode of the plate electrode PL50 and the capacitor electrode PC53 define the capacitor C5 in FIG. 2.

The plate electrode PL51 is line symmetric with respect to the imaginary line CL in plan view of the multilayer body 110 in the stacking direction. The capacitor electrode PC51 and the capacitor electrode PC52 are line symmetric with respect to the imaginary line CL. That is, as for the filter device 100A, the elements that are disposed in the multilayer body 110 are symmetrical with respect to the imaginary line CL.

With the structure of the filter device 100A illustrated in FIG. 8, the equivalent circuit illustrated in FIG. 2 can be provided as described above. Accordingly, the filter device 100A can achieve the same or substantially the same advantageous effects as those of the filter device 100 according to the first example embodiment.

The “plate electrode PL51”, the “capacitor electrode PC51”, the “capacitor electrode PC51”, and the “ground electrode PG2” according to the first modification correspond to a “fourth electrode” to a “seventh electrode”.

### Second Modification

In a structure described according to a second modification of an example embodiment of the present invention, the resonators RC1 and RC3 in the filter device 100 according to the first example embodiment are capacitively grounded with a capacitor interposed therebetween.

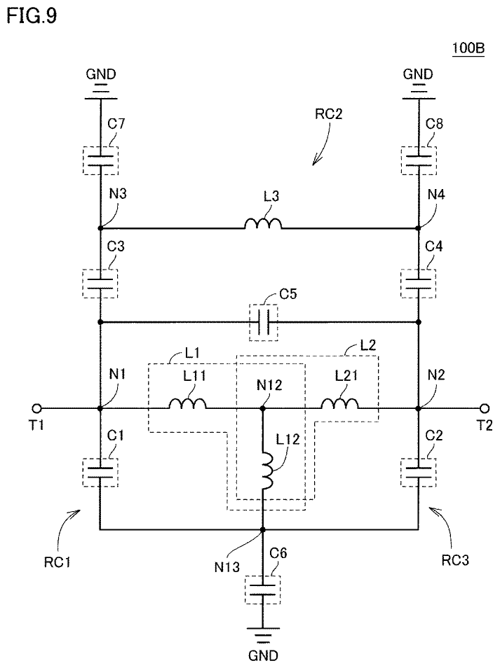

FIG. 9 is an equivalent circuit diagram of a filter device 100B according to the second modification. The structure of the filter device 100B is provided by adding a capacitor C6 into the equivalent circuit diagram of the filter device 100 illustrated in FIG. 2. In FIG. 9, the structure except for the capacitor C6 is the same or substantially the same as that in FIG. 2, and a duplicated description for the elements in FIG. 2 is not repeated.

Referring to FIG. 9, the capacitor C6 is connected between the ground terminal GND and a connection node N13 of the capacitor C1 of the resonator RC1, the capacitor C2 of the resonator RC3, the inductor L12 that is shared by the resonator RC1 and the resonator RC3.

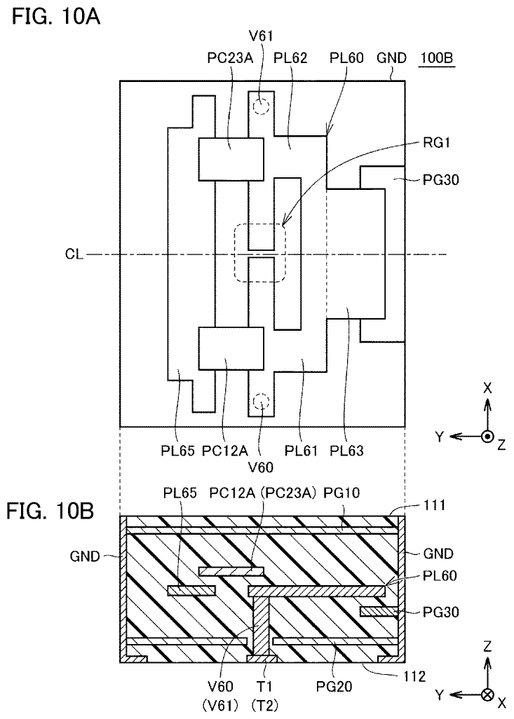

FIG. 10A illustrates a plan view and FIG. 10B illustrates a transparent side view of an example of the structure of the filter device 100B in FIG. 9. As for the filter device 100B, the resonators include only the plate electrodes without a via as in the first modification in FIG. 8. The filter device 100B includes the input terminal T1, the output terminal T2, the ground terminal GND, plate electrodes PL60 and PL65, capacitor electrodes PC12A and PC23A, ground electrodes PG10, PG20, and PG30, and vias V60 and V61.

The filter device 100B includes the multilayer body 110 in which multiple dielectric layers are stacked. The ground terminal GND is disposed on the side surfaces and a portion of the lower surface 112 of the multilayer body 110. The ground electrodes PG10 and PG20 are disposed over the entire or substantially the entire surface of each of the dielectric layers adjacent to the upper surface 111 and the lower surface 112 of the multilayer body 110. The side surfaces of the ground electrodes PG10 and PG20 are connected to the ground terminal GND.

The plate electrode PL60 that is included in the resonators RC1 and RC3 and the plate electrode PL65 that is included in the resonator RC2 are disposed in the same dielectric layer between the ground electrode PG10 and the ground electrode PG20 in the multilayer body 110.

The plate electrode PL60 includes a first electrode PL61 that is connected to the input terminal T1 that is disposed in or on the lower surface 112 with the via V60 interposed therebetween, a second electrode PL62 that is connected to the output terminal T2 that is disposed in or on the lower surface 112 with the via V61 interposed therebetween, and a third electrode PL63 that is connected to the first electrode PL61 and the second electrode PL62. The first electrode PL61 and the second electrode PL62 have a Y-shape or a substantially Y-shape that include three end portions and are symmetrical.

The via V60 is connected to a first end portion of the first electrode PL61. The via V61 is connected to a first end portion of the second electrode PL62. A second end portion of the first electrode PL61 and a second end portion of the second electrode PL62 are connected to each other. A third end portion of the first electrode PL61 and a third end portion of the second electrode PL62 are spaced a predetermined distance from each other and face each other (a region RG1). A facing portion in the region RG1 defines the capacitor C5 in FIG. 9.

The third electrode PL63 has a rectangular or substantially rectangular shape and is connected to the second end portions of the first electrode PL61 and the second electrode PL62. The third electrode PL63 is not connected to the ground terminal GND on the side surfaces.

An inductance component (corresponding to the inductor L1 in FIG. 9) in the first electrode PL61 and the third electrode PL63 and a capacitance component (corresponding to the capacitor C1 in FIG. 9) between this portion and the ground electrodes PG10 and PG20 define the resonator RC1. An inductance component (corresponding to the inductor L2 in FIG. 9) in the second electrode PL62 and the third electrode PL63 and a capacitance component (corresponding to the capacitor C2 in FIG. 9) between this portion and the ground electrodes PG10 and PG20 define the resonator RC3.

The ground electrode PG30 is a plate electrode that has a rectangular or substantially rectangular shape that extends in the X-axis direction and is connected to the ground terminal GND on the side surface adjacent to the third electrode PL63. The ground electrode PG30 is disposed in the dielectric layer that differs from the dielectric layer in which the third electrode PL63 is disposed and at least partially overlaps the third electrode PL63 in plan view of the multilayer body 110 in the stacking direction (the Z-axis direction). That is, the third electrode PL63 and the ground electrode PG30 define the capacitor C6 in FIG. 9.

The plate electrode PL65 extends along and is adjacent to the second end portions of the first electrode PL61 and the second electrode PL62 that extend in the X-axis direction and has a rectangular or substantially rectangular shape. A capacitance component due to the plate electrode PL65 and the ground electrodes PG10 and PG20 defines the capacitors C7 and C8 in FIG. 9.

The capacitor electrodes PC12A and PC23A are disposed in the dielectric layer that differs from the dielectric layer in which the plate electrodes PL60 and PL65 are disposed and has a rectangular or substantially rectangular shape. The capacitor electrode PC12A partially overlaps the first electrode PL61 and the plate electrode PL65 in plan view of the multilayer body 110 in the stacking direction. That is, the first electrode PL61, the plate electrode PL65, and the capacitor electrode PC12A define the capacitor C3 in FIG. 9.

Similarly, the capacitor electrode PC23A partially overlaps the second electrode PL62 and the plate electrode PL65 in plan view of the multilayer body 110 in the stacking direction. That is, the second electrode PL62, the plate electrode PL65, and the capacitor electrode PC23A define the capacitor C4 in FIG. 9.

With the structure described above, the resonant frequencies of the resonators RC1 and RC3 can change depending on the dimension of the plate electrode PL60 in the Y-axis direction. If the third electrode PL63 at the plate electrode PL60 is connected to the ground terminal GND, and during cutting with a dicing machine, a cutting error is made or stacking misalignment of the dielectric layers occurs, the dimension of the third electrode PL63 in the Y-axis direction changes, and the filter characteristic is greatly affected.

According to the second modification, the resonators RC1 and RC3 are capacitively grounded by the ground electrode PG30, and consequently, the dimension of the third electrode PL63 can be prevented from changing due to the cutting error or the stacking misalignment. Accordingly, variations in characteristics in the manufacturing process can be reduced.

According to the present modification, the “plate electrode PL65”, the “capacitor electrode PC12A”, the “capacitor electrode PC23A”, and the “ground electrode PG30” correspond to the “fourth electrode” to the “seventh electrode”.

### Third Modification

In a structure described according to a third modification of an example embodiment of the present invention, the resonator RC1 and the resonator RC3 are connected to the input terminal and the output terminal with capacitors interposed therebetween.

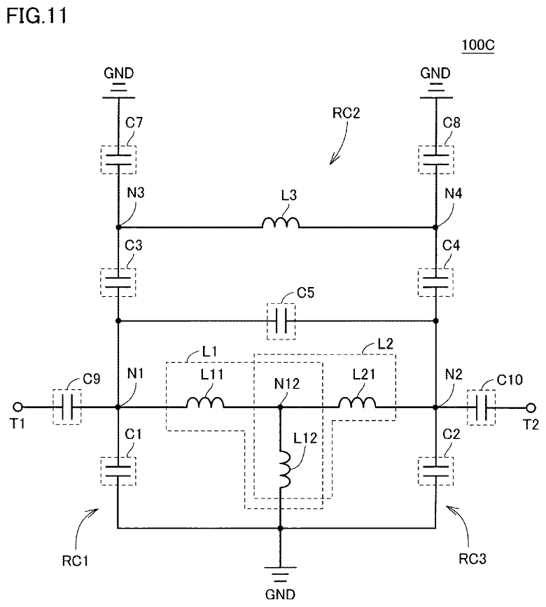

FIG. 11 is an equivalent circuit diagram of a filter device 100C according to the third modification. The structure of the filter device 100C is acquired by adding capacitors C9 and C10 into the filter device 100 according to the first example embodiment illustrated in FIG. 2. As for FIG. 11, a duplicated description for the elements in FIG. 2 is not repeated.

Referring to FIG. 11, as for the filter device 100C, the capacitor C9 is connected between the input terminal T1 and the connection node N1 of the resonator RC1, and the capacitor C10 is connected between the output terminal T2 and the connection node N2 of the resonator RC3. The capacitors are thus disposed between the resonators and the input and output terminals, and consequently, a DC component in a signal can be cut. This enables the attenuation characteristics to be reduced or prevented from being degraded due to the DC component. In addition, the capacitors C9 and C10 enable impedance matching between the filter device and an external device to be adjusted in the pass band.

In particular, as for a structure in which resonators RC1 and RC3 are capacitively grounded by using a shunt capacitor as in the second modification illustrated in FIG. 9, portions of the resonators and the shunt capacitor define a low pass filter, and accordingly, the attenuation characteristics near DC are likely to be degraded. For this reason, the use of the structure of the filter device 100B according to the second modification enables the filter characteristics to be reduced or prevented from being degraded in some cases.

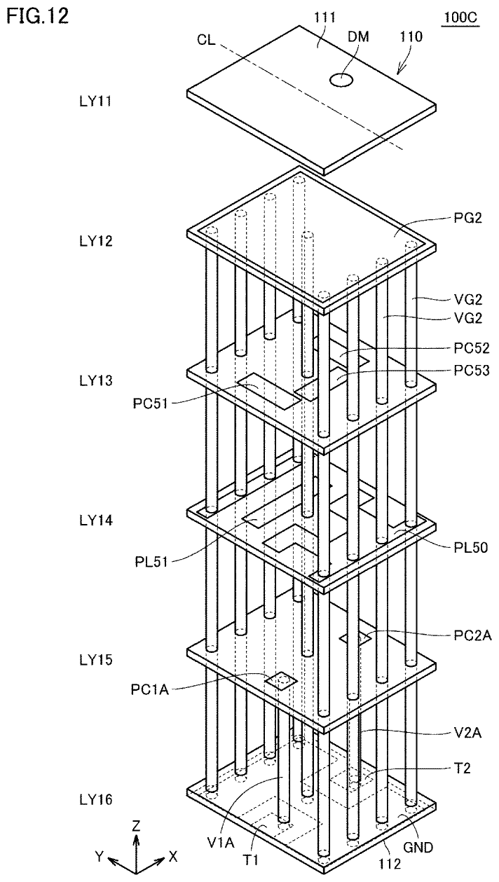

FIG. 12 is an exploded perspective view of an example of the multilayer structure of the filter device 100C in FIG. 11. The filter device 100C differs from the filter device 100A according to the first modification illustrated in FIG. 8 by including different connection portions between the input terminal T1 and the plate electrode PL50 and between the output terminal T2 and the plate electrode PL50. The other structure is the same or substantially the same as that in FIG. 8, and a duplicated description for the elements in FIG. 8 is not repeated.

Specifically, the input terminal T1 is connected to a capacitor electrode PC1A that is disposed in the dielectric layer LY15 by using a via V1A. The capacitor electrode PC1A at least partially overlaps the plate electrode PL50 in plan view of the multilayer body 110 in the stacking direction. The capacitor electrode PC1A and the plate electrode PL50 define the capacitor C9 in FIG. 11.

Similarly, the output terminal T2 is connected to a capacitor electrode PC2A that is disposed in the dielectric layer LY15 by using a via V2A. The capacitor electrode PC2A at least partially overlaps the plate electrode PL50 in plan view of the multilayer body 110 in the stacking direction. The capacitor electrode PC2A and the plate electrode PL50 define the capacitor C10 in FIG. 11.

With this structure, the circuit illustrated in FIG. 11 can be provided, and the attenuation characteristics can be reduced or prevented from being degraded due to the DC component.

According to the third modification, the “capacitor C9” and the “capacitor C10” correspond to a “ninth capacitor” and a “tenth capacitor”.

### Fourth Modification

In a structure described according to a fourth modification of an example embodiment of the present invention, the inductor L3 of the resonator RC2 is not grounded.

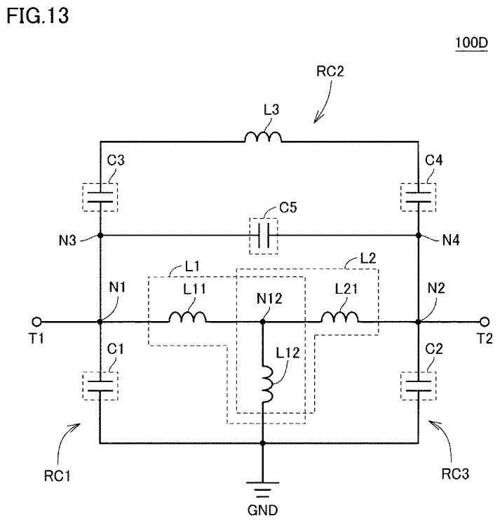

FIG. 13 is an equivalent circuit diagram of a filter device 100D according to the fourth modification. The structure of the filter device 100D is provided by removing the capacitors C6 and C7 in the filter device 100 illustrated in FIG. 2. Also, with this structure, the resonator RC2 that includes the inductor L3 and the capacitors C3 and C4 is the resonator of the both-ends open type, and accordingly, the same or substantially the same advantageous effects as those of the filter device 100 according to the first example embodiment can be achieved.

### Fifth Modification

In a structure described according to a fifth modification of an example embodiment of the present invention, a portion of the capacitor of the second-tier resonator is used for capacitive coupling between the first-tier resonator and the third-tier resonator.

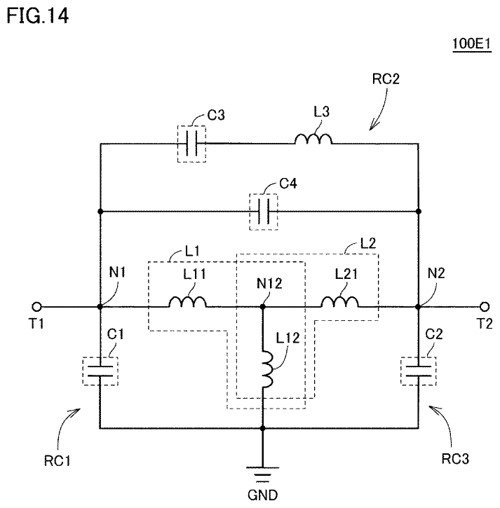

FIG. 14 is an equivalent circuit diagram of a filter device 100E1 according to the fifth modification. As for the filter device 100E1, the capacitor C4 is disposed at the position of the capacitor C5 in the filter device 100D illustrated in FIG. 13. In other words, as for the resonator RC2 of the both-ends open type in which the capacitors C3 and C4 are connected, a connection node of the inductor L3 and the capacitor C4 is connected to the connection node N2 of the resonator RC3, a connection node of the capacitor C3 and the capacitor C4 is connected to the connection node N1 of the resonator RC1. From another perspective, the resonator RC2 in the filter device 100D in FIG. 13 is replaced with an LC series resonator that includes the inductor L3 and the capacitor C3.

The resonator RC2 is capacitively coupled with the resonator RC1 and is magnetically coupled with the resonator RC3. For this reason, also with this structure, the resonator RC1 and the resonator RC3 are capacitively coupled with each other and are magnetically coupled with each other, and the polarity of coupling between the resonator RC2 and the resonator RC1 and the polarity of coupling between the resonator RC2 and the resonator RC3 are opposite to each other. Accordingly, the structure of the filter device 100E1 enables the same or substantially the same advantageous effects as those of the filter device 100 according to the first example embodiment to be achieved.

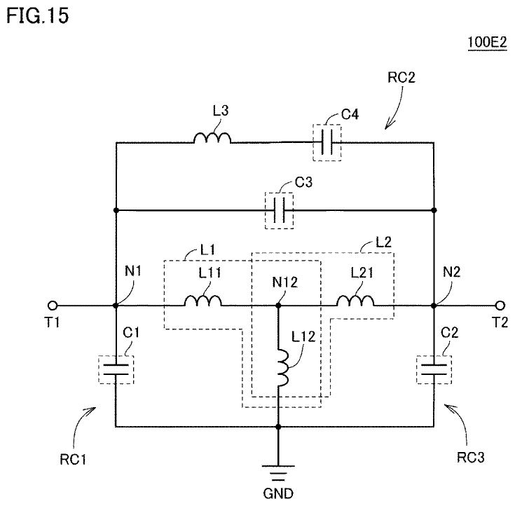

In the description for the structure of the filter device 100E1, the resonator RC1 and the resonator RC3 are capacitively coupled with each other by the capacitor C4 of the resonator RC2. However, the resonator RC1 and the resonator RC3 may be capacitively coupled with each other by the capacitor C3 of the resonator RC2 as in a filter device 100E2 illustrated in FIG. 15.

### Sixth Modification

In the description for the structures according to the first example embodiment and the first to fifth modifications, the first-tier resonator and the third-tier resonator share portions of the inductors and are consequently magnetically coupled with each other. In a structure described according to a sixth modification of an example embodiment of the present invention, the first-tier resonator and the third-tier resonator are LC parallel resonators that are separated from each other.

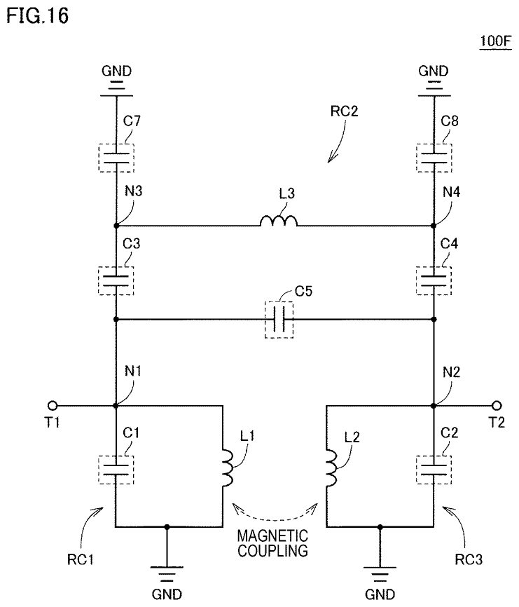

FIG. 16 is an equivalent circuit diagram of a filter device 100F according to the sixth modification. As for the filter device 100F, the inductor L1 that is included in the resonator RC1 and the inductor L2 that is included in the resonator RC3 are separated from each other. Vias or wiring patterns that are included in the inductor L1 and the inductor L2 are adjacent to each other in the multilayer body 110 so as to be magnetically coupled with each other. Also, in the case where the resonators RC1 and RC3 are separated from each other, the same or substantially the same advantageous effects as those according to the first example embodiment can be achieved.

As for the filter device 100F in FIG. 16, the capacitor C5 that capacitively couples the resonator RC1 and the resonator RC3 with each other is individually provided, but the capacitor electrode that is included in the capacitor C1 of the resonator RC1 may be adjacent to the capacitor electrode that is included in the capacitor C2 of the resonator RC3, and a stray capacitance between these capacitor electrodes may define the capacitor C5.

### Second Example Embodiment

In the case described regarding the filter device 100 according to the first example embodiment, coupling between the first-tier resonator and the second-tier resonator and coupling between the second-tier resonator and the third-tier resonator is the capacitive coupling. In a structure described according to a second example embodiment and seventh and eighth modifications described later, coupling between the first-tier resonator and the second-tier resonator and coupling between the second-tier resonator and the third-tier resonator are the magnetic coupling.

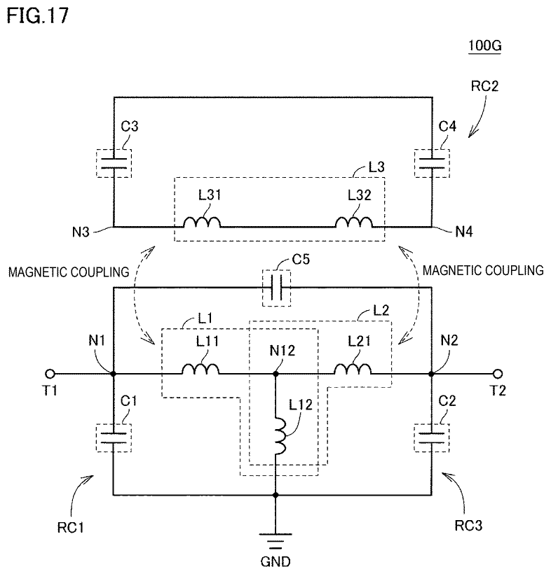

FIG. 17 an equivalent circuit diagram of a filter device 100G according to a second example embodiment of the present invention. The filter device 100G is acquired by removing the capacitors C7 and C8 in the filter device 100 according to the first example embodiment illustrated in FIG. 2. As for the filter device 100G, the capacitors C3 and C4 are not connected to the resonators RC1 and RC3 and are connected to each other.

As for the filter device 100G, the inductor L3 is magnetically coupled with the inductor L1 of the resonator RC1 and the inductor L2 of the resonator RC3. More specifically, in FIG. 17, the inductor L3 is illustrated as inductors L31 and L32 that are connected in series, a portion of the inductor L31 is magnetically coupled with a portion of the inductor L11 in the inductor L1, and a portion of the inductor L32 is magnetically coupled with a portion of the inductor L21 of the inductor L2.

Also in the case where the resonator RC2 is magnetically coupled with the resonator RC1 and the resonator RC3, the resonator RC2 is thus the resonator of the both-ends open type, and consequently, the polarity of coupling between the resonator RC1 and the resonator RC2 and the polarity of coupling between the resonator RC2 and the resonator RC3 are opposite to each other. This enables the attenuation poles to be generated on the signal transmission path that extends from the resonator RC1 to the resonator RC3 via the resonator RC2. Accordingly, the two attenuation poles are generated together with the cross coupling between the resonator RC1 and the resonator RC3, and the filter device can define and function as the band pass filter.

According to the second example embodiment, the “inductor L31” and the “inductor L32” correspond to a “fourth inductor” and a “fifth inductor”.

### Seventh Modification

In a structure described according to a seventh modification of an example embodiment of the present invention, the capacitors of the second-tier resonator in the filter device 100G according to the second example embodiment are connected to ground terminals.

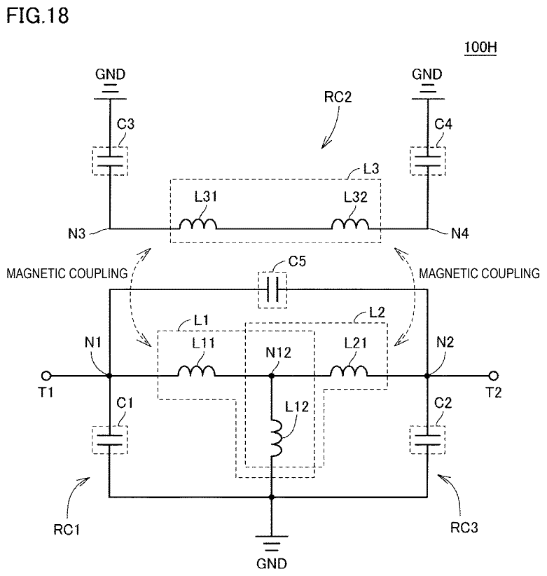

FIG. 18 is an equivalent circuit diagram of a filter device 100H according to the seventh modification. As for the filter device 100H, a first end of the capacitor C3 in the resonator RC2 is connected to the inductor L31 (the connection node N3), and a second end thereof is connected to the ground terminal GND. Similarly, a first end of the capacitor C4 in the resonator RC2 is connected to the inductor L32 (the connection node N4), and a second end thereof is connected to the ground terminal GND.

As for the filter device 100H, the inductor L31 of the resonator RC2 is magnetically coupled with the inductor L11 of the resonator RC1, and the inductor L32 of the resonator RC2 is magnetically coupled with the inductor L21 of the resonator RC3.

Also with the structure of the filter device 100H, the resonator RC2 is configured as the resonator of the both-ends open type, and accordingly, the same or substantially the same advantageous effects as those of the filter device 100 according to the first example embodiment and the filter device 100G according to the second example embodiment can be achieved.

### Eighth Modification

In a structure described according to an eighth modification of an example embodiment of the present invention, the inductors of the second-tier resonator in the filter device 100G according to the second example embodiment are grounded.

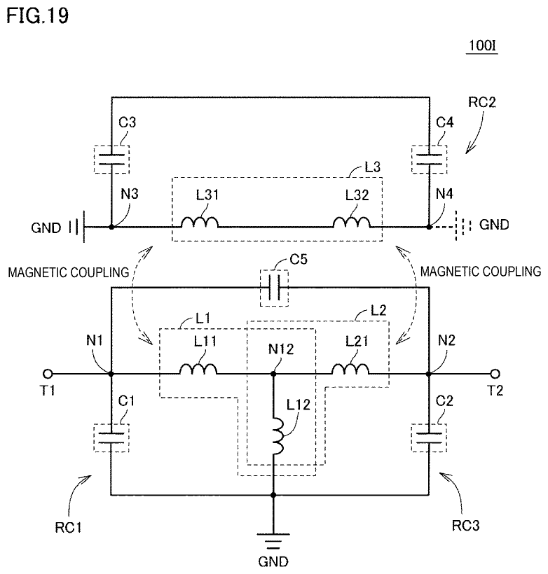

FIG. 19 is an equivalent circuit diagram of a filter device 100I according to the eighth modification. As for the filter device 100I, the connection node N3 between the inductor L3 and the capacitor C3 of the resonator RC2 in the structure of the filter device 100G and/or the connection node N4 between the inductor L3 and the capacitor C4 is connected to the ground terminal GND.

Also with the structure of the filter device 100I, the resonator RC2 is configured as the resonator of the both-ends open type, and accordingly, the same or substantially the same advantageous effects as those of the filter device 100 according to the first example embodiment and the filter device 100G according to the second example embodiment can be achieved.

### Third Example Embodiment

In the case described according to a third example embodiment of the present invention, a filter device has a six-tier structure including two sets of the filter structures described according to the first example embodiment.

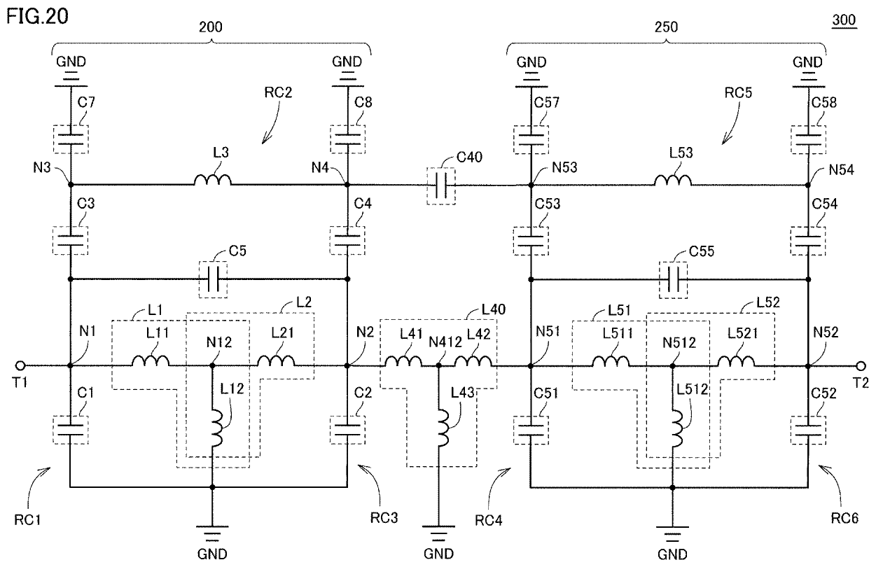

FIG. 20 is an equivalent circuit diagram of a filter device 300 according to the third example embodiment. The filter device 300 includes two filter circuits 200 and 250 and a capacitor C40 and an inductor L40 for connecting the filter circuits. The inductor L40 includes inductors L41 to L43.

The filter circuits 200 and 250 have a structure that corresponds to the circuit of the filter device 100 according to the first example embodiment. Elements that are included in the filter circuit 200 are designated by the same or similar reference signs as those of the elements of the filter device 100 according to the first example embodiment.

Resonators RC4 to RC6 in the filter circuit 250 correspond to the resonators RC1 to RC3 in the filter device 100. Capacitors C51 to C55, C57, and C58 in the filter circuit 250 correspond to the capacitors C1 to C5, C7, and C8 in the filter device 100. Inductors L51 to L53, L511, L512, and L521 in the filter circuit 250 correspond to inductors L1 to L3, L11, L12, and L21 in the filter device 100. The connection nodes N1 to N4 and N12 in the filter circuit 250 correspond to connection nodes N51 to N54 and N512 in the filter device 100.

The connection node N1 of the filter circuit 200 is connected to the input terminal T1. The connection node N52 of the filter circuit 250 is connected to the output terminal T2. The inductors L41 and L42 are connected in series between the connection node N2 of the filter circuit 200 and the connection node N51 of the filter circuit 250. The inductor L43 is connected between the ground terminal GND and a connection node N412 of the inductor L41 and the inductor L42. That is, the resonator RC3 of the filter circuit 200 and the resonator RC4 of the filter circuit 250 are magnetically coupled with each other.

The capacitor C40 is connected between the connection node N4 of the filter circuit 200 and a connection node N53 of the filter circuit 250. That is, the electric field coupling occurs between the resonator RC2 of the filter circuit 200 and the resonator RC5 of the filter circuit 250.

With this structure, the two attenuation poles can be generated in the higher frequency region and the lower frequency region than the pass band at the filter circuits 200 and 250 of the three-tier structure, and accordingly, the filter device can define and function as the band pass filter. In addition, a passing signal passes through a larger number of the resonators than that according to the first example embodiment, and accordingly, the attenuation can be larger than that of the filter device 100 according to the first example embodiment.

As illustrated in FIG. 20, the filter circuits 200 and 250 are symmetrical, and the filter device 300 has a symmetrical structure overall. This enables the variations in characteristics to be reduced due to the arrangement error in the manufacturing process.

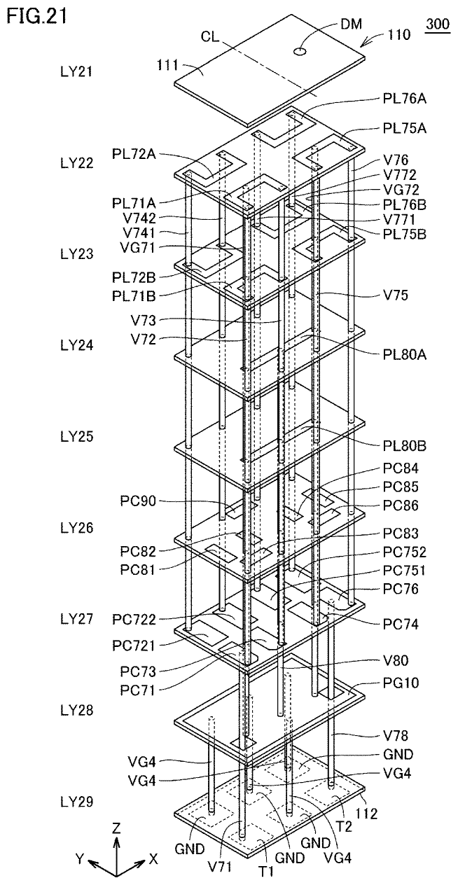

FIG. 21 is an exploded perspective view of a first example of the multilayer structure of the filter device 300 according to the third example embodiment. In FIG. 21, inductors and capacitors that are included in the filter device 300 include vias and wiring patterns.

The multilayer body 110 of the filter device 300 includes dielectric layers LY21 to LY29 that are stacked in the stacking direction (the Z-axis direction).

The directional mark DM to identify the direction of the filter device 300 is disposed on the upper surface 111 (the dielectric layer LY21: the first surface) of the multilayer body 110, and external terminals (the input terminal T1, the output terminal T2, and the multiple ground terminals GND) to connect the filter device 300 and an external device to each other are disposed in or on the lower surface 112 (the dielectric layer LY29: the second surface) of the multilayer body 110. The input terminal T1, the output terminal T2, and the ground terminals GND are electrodes that have a plate shape and are the LGA terminals that are regularly disposed in or on the lower surface 112 of the multilayer body 110.

The structure of the filter circuit 200 will now be described. The input terminal T1 is connected to a capacitor electrode PC71 that is disposed in the dielectric layer LY27 by using a via V71. The capacitor electrode PC71 is a plate electrode that has a rectangular or substantially rectangular shape that extends in the Y-axis direction. At least a portion of the capacitor electrode PC71 overlaps the ground electrode PG10 that is disposed in the dielectric layer LY28 in plan view of the multilayer body 110 in the stacking direction.

The ground electrode PG10 is disposed over the entire or substantially the entire surface of the dielectric layer LY28 and is connected to the ground terminals GND that are disposed in the dielectric layer LY29 by using multiple vias VG4. The capacitor electrode PC71 and the ground electrode PG10 define the capacitor C1 in FIG. 20. The via V71 extends through the ground electrode PG10.

The capacitor electrode PC71 is connected to a plate electrode PL71A that is disposed in the dielectric layer LY22 and a plate electrode PL71B that is disposed in the dielectric layer LY23 by using a via V72. The plate electrodes PL71A and PL71B are belt-shaped electrodes that have a C-shape or substantially C-shape that includes an opening in a Y-axis negative direction in plan view of the multilayer body 110 in the stacking direction. The plate electrode PL71A and the plate electrode PL71B have the same or substantially the same shape.

The via V72 is connected to first ends of the plate electrodes PL71A and PL71B, and a via V73 is connected to second ends thereof. The via V73 is connected to a capacitor electrode PC73 that is disposed in the dielectric layer LY27. The capacitor electrode PC73 has the same or substantially the same shape as the capacitor electrode PC71 and is disposed in the X-axis positive direction with respect to the capacitor electrode PC71. At least a portion of the capacitor electrode PC73 overlaps the ground electrode PG10 in the dielectric layer LY28 in plan view of the multilayer body 110 in the stacking direction. The capacitor electrode PC73 and the ground electrode PG10 define the capacitor C2 in FIG. 20.

A via VG71 is connected to the centers of paths that extend from the first ends of the plate electrodes PL71A and PL71B to the second ends thereof. The via VG71 is connected to the ground electrode PG10 in the dielectric layer LY28. The vias V72 and VG71 and the plate electrodes PL71A and PL71B define the inductor L1 in FIG. 20. Similarly, the vias V73 and VG71 and the plate electrodes PL71A and PL71B define the inductor L2 in FIG. 20.

In the dielectric layer LY27, a capacitor electrode PC721 that is spaced from the capacitor electrode PC71 is disposed in the Y-axis positive direction with respect to the capacitor electrode PC71. In addition, a capacitor electrode PC722 that is spaced from the capacitor electrode PC73 is disposed in the Y-axis positive direction with respect to the capacitor electrode PC73. The capacitor electrodes PC721 and PC722 have a rectangular or substantially rectangular shape, are plate electrodes that have the same or substantially the same shape, and at least partially overlap the ground electrode PG10 in the dielectric layer LY28 in plan view of the multilayer body 110 in the stacking direction. The capacitor electrodes PC721 and PC722 and the ground electrode PG10 define the capacitor C7 and the capacitor C8 in FIG. 20.

The capacitor electrode PC721 is connected to a plate electrode PL72A that is disposed in the dielectric layer LY22 and a plate electrode PL72B that is disposed in the dielectric layer LY23 by a via V741. The plate electrodes PL72A and PL72B are belt-shaped electrodes that have a C-shape or substantially C-shape that includes an opening in the Y-axis positive direction in plan view of the multilayer body 110 in the stacking direction. The plate electrode PL72A and the plate electrode PL72B have the same or substantially the same shape.

The via V741 is connected to first ends of the plate electrodes PL72A and PL72B, and a via V742 is connected to second ends thereof. The via V742 is connected to the capacitor electrode PC722 in the dielectric layer LY27.

Capacitor electrodes PC81, PC82, and PC83 that have a rectangular or substantially rectangular shape are disposed in the dielectric layer LY26. The capacitor electrode PC81 partially overlaps the capacitor electrode PC71 and the capacitor electrode PC721 in plan view of the multilayer body 110 in the stacking direction. The capacitor electrodes PC71, PC721, and PC81 define the capacitor C3 in FIG. 20.

The capacitor electrode PC82 partially overlaps the capacitor electrode PC73 and the capacitor electrode PC722 in plan view of the multilayer body 110 in the stacking direction. The capacitor electrodes PC73, PC722, and PC82 define the capacitor C4 in FIG. 20.

The capacitor electrode PC83 partially overlaps the capacitor electrode PC71 and the capacitor electrode PC73 in plan view of the multilayer body 110 in the stacking direction. The capacitor electrodes PC71, PC73, and PC83 define the capacitor C5 in FIG. 20.

The filter circuit 250 will now be described. The output terminal T2 is connected to a capacitor electrode PC76 that is disposed in the dielectric layer LY27 by using a via V78. The capacitor electrode PC76 is a plate electrode that has a rectangular or substantially rectangular shape in the Y-axis direction. At least a portion of the capacitor electrode PC76 overlaps the ground electrode PG10 in the dielectric layer LY28 in plan view of the multilayer body 110 in the stacking direction. The capacitor electrode PC76 and the ground electrode PG10 define the capacitor C52 in FIG. 20.

A capacitor electrode PC78 is connected to a plate electrode PL75A that is disposed in the dielectric layer LY22 and a plate electrode PL75B that is disposed in the dielectric layer LY23 by a via V76. The plate electrodes PL75A and PL75B are belt-shaped electrodes that have a C-shape or substantially C-shape that includes an opening in the Y-axis negative direction in plan view of the multilayer body 110 in the stacking direction. The plate electrode PL75A and the plate electrode PL75B have the same or substantially the same shape.

The via V76 is connected to first ends of the plate electrodes PL75A and PL75B, and a via V75 is connected to second ends thereof. The via V75 is connected to a capacitor electrode PC74 that is disposed in the dielectric layer LY27. The capacitor electrode PC74 has the same or substantially the same shape as the capacitor electrode PC76 and is disposed in the X-axis negative direction with respect to the capacitor electrode PC71. At least a portion of the capacitor electrode PC74 overlaps the ground electrode PG10 in the dielectric layer LY28 in plan view of the multilayer body 110 in the stacking direction. The capacitor electrode PC74 and the ground electrode PG10 define the capacitor C51 in FIG. 20.

A via VG72 is connected to the centers of paths that extend from the first ends of the plate electrodes PL75A and PL75B to the second ends thereof. The via VG72 is connected to the ground electrode PG10 in the dielectric layer LY28. The vias V75 and VG72 and the plate electrodes PL75A and PL75B define the inductor L51 in FIG. 20. Similarly, the vias V76 and VG72 and the plate electrodes PL75A and PL75B define the inductor L52 in FIG. 20.

In the dielectric layer LY27, a capacitor electrode PC751 that is spaced from the capacitor electrode PC74 is disposed in the Y-axis positive direction with respect to the capacitor electrode PC74. A capacitor electrode PC752 that is spaced from the capacitor electrode PC76 is disposed in the Y-axis positive direction with respect to the capacitor electrode PC76. The capacitor electrodes PC751 and PC752 have a rectangular or substantially rectangular shape, are plate electrodes that have the same or substantially the same shape, and at least partially overlaps the ground electrode PG10 in the dielectric layer LY28 in plan view of the multilayer body 110 in the stacking direction. The capacitor electrodes PC751 and PC752 and the ground electrode PG10 define the capacitor C57 and the capacitor C58 in FIG. 20.

The capacitor electrode PC751 is connected to a plate electrode PL76A that is disposed in the dielectric layer LY22 and a plate electrode PL76B that is disposed in the dielectric layer LY23 by using a via V771. The plate electrodes PL76A and PL76B are belt-shaped electrodes that have a C-shape or substantially C-shape that includes an opening in the Y-axis positive direction in plan view of the multilayer body 110 in the stacking direction. The plate electrode PL76A and the plate electrode PL76B have the same or substantially the same shape.

The via V771 is connected to first ends of the plate electrodes PL76A and PL76B, and a via V772 is connected to second ends thereof. The via V772 is connected to the capacitor electrode PC752 in the dielectric layer LY27.

In the dielectric layer LY26, capacitor electrodes PC84, PC85, and PC86 that have a rectangular or substantially rectangular shape are provided. The capacitor electrode PC84 partially overlaps the capacitor electrode PC74 and the capacitor electrode PC751 in plan view of the multilayer body 110 in the stacking direction. The capacitor electrodes PC74, PC751, and PC84 define the capacitor C53 in FIG. 20.

The capacitor electrode PC85 partially overlaps the capacitor electrode PC76 and the capacitor electrode PC752 in plan view of the multilayer body 110 in the stacking direction. The capacitor electrodes PC76, PC752, and PC85 define the capacitor C54 in FIG. 20.

The capacitor electrode PC86 partially overlaps the capacitor electrode PC74 and the capacitor electrode PC76 in plan view of the multilayer body 110 in the stacking direction. The capacitor electrodes PC74, PC76, and PC86 define the capacitor C55 in FIG. 20.

In the dielectric layer LY26, a capacitor electrode PC90 that has a rectangular or substantially rectangular shape that extends in the X-axis direction is disposed. The capacitor electrode PC90 partially overlaps the capacitor electrode PC722 and the capacitor electrode PC751 in the dielectric layer LY26 in plan view of the multilayer body 110 in the stacking direction. That is, the capacitor electrodes PC90, PC722, and PC751 define the capacitor C40 in FIG. 20.

The via VG71 in the filter circuit 200 and the via VG72 in the filter circuit 250 are connected to each other by a plate electrode PL80A that is disposed in the dielectric layer LY24 and a plate electrode PL80B that is disposed in the dielectric layer LY25. The plate electrodes PL80A and PL80B have a rectangular or substantially rectangular shape that extends in the X-axis direction. A via V80 is connected to central portions in the direction in which the plate electrodes PL80A and PL80B extend. The via V80 is connected to the plate electrodes PL80A and PL80B and the ground electrode PG10. The plate electrodes PL80A and PL80B and the via V80 define the inductors L41 to L43 in FIG. 20.

As illustrated in FIG. 21, elements that are disposed in the multilayer body 110 in the filter device 300 are line symmetric with respect to the imaginary line CL.

The circuit illustrated in FIG. 20 is acquired by using the structure illustrated in FIG. 21 as described above.

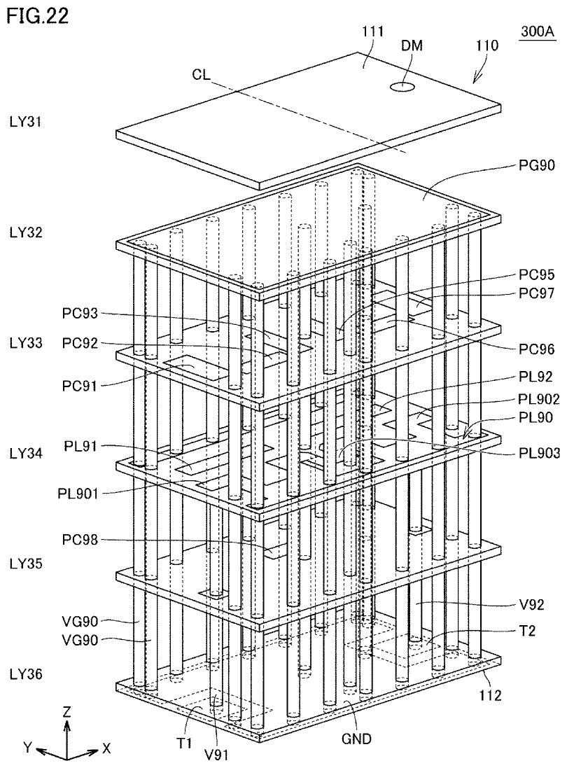

FIG. 22 is an exploded perspective view of a filter device 300A that has a multilayer structure that differs from that in FIG. 20. In FIG. 22, inductors and capacitors that are included in the filter device 300A include wiring patterns.

The filter device 300A that includes two structures that are the same or substantially the same as the structure of the filter device 100A illustrated in FIG. 8 and that are adjacent to each other in the X-axis direction. The multilayer body 110 of the filter device 300A includes dielectric layers LY31 to LY36 that are stacked in the stacking direction.

The directional mark DM to identify the direction of the filter device 300A is disposed on the upper surface 111 (the dielectric layer LY31: the first surface) of the multilayer body 110. The input terminal T1, the output terminal T2, and the ground terminal GND to connect the filter device 300A and an external device are disposed in or on the lower surface 112 (the dielectric layer LY36: the second surface) of the multilayer body 110. The ground terminal GND is a plate electrode that is partially notched and that has an H-shape or substantially H-shape. The input terminal T1 is disposed in the notched portion of the dielectric layer LY36 in the X-axis negative direction. The input terminal T1 is disposed in the notched portion of the dielectric layer LY36 in the X-axis positive direction.

In the dielectric layer LY32, a ground electrode PG90 covers the entire or substantially the entire surface of the dielectric layer. The ground electrode PG90 is connected to the ground terminal GND in the dielectric layer LY36 by multiple vias VG90 that are located on the circumference of the multilayer body 110 along the side surfaces of the multilayer body 110.

The input terminal T1 that is disposed in or on the lower surface 112 of the multilayer body 110 is connected to a plate electrode PL90 that is disposed in the dielectric layer LY34 by a via V91. The plate electrode PL90 has a shape such that a wiring pattern PL903 that has a C-shape or substantially C-shape connects two wiring patterns PL901 and PL902 that correspond to the plate electrode PL50 in FIG. 8.

The via V91 is connected to a first electrode of the wiring pattern PL901. A second electrode of the wiring pattern PL901 is connected to a first electrode of the wiring pattern PL902 with the wiring pattern PL903 interposed therebetween. A second electrode of the wiring pattern PL902 is connected to the output terminal T2 with a via V92 interposed therebetween. A third electrode of the wiring pattern PL901 is connected to a third electrode of the wiring pattern PL902.

An inductance component of the wiring pattern PL901 and a capacitance component of the wiring pattern PL901 define the resonators RC1 and RC3 in FIG. 20. An inductance component of the wiring pattern PL902 and a capacitance component of the wiring pattern PL902 define the resonators RC4 and RC6 in FIG. 20. The wiring pattern PL903 defines the inductor L40 in FIG. 20.

In the dielectric layer LY34, a plate electrode PL91 is adjacent to the first electrode and the second electrode of the wiring pattern PL901. The plate electrode PL91 has a rectangular or substantially rectangular shape that extends in the X-axis direction. An inductance component of the plate electrode PL91 defines the inductor L3 in FIG. 20. A capacitance component of the plate electrode PL91 defines the capacitors C7 and C8 in FIG. 20. Similarly, a plate electrode PL92 is adjacent to the first electrode and the second electrode of the wiring pattern PL902. The plate electrode PL92 has a rectangular or substantially rectangular shape that extends in the X-axis direction. An inductance component of the plate electrode PL92 defines the inductor L53 in FIG. 20. A capacitance component of the plate electrode PL92 defines the capacitors C57 and C58 in FIG. 20.

In the dielectric layer LY33, capacitor electrodes PC91 to PC93, and PC95 to PC97 that have a rectangular or substantially rectangular shape are provided. The capacitor electrode PC91 partially overlaps the first electrode of the wiring pattern PL901 and the plate electrode PL91 in plan view of the multilayer body 110 in the stacking direction. The first electrode of the wiring pattern PL901, the plate electrode PL91, and the capacitor electrode PC91 define the capacitor C3 in FIG. 20. The capacitor electrode PC93 partially overlaps the second electrode of the wiring pattern PL901 and the plate electrode PL91 in plan view of the multilayer body 110 in the stacking direction. The second electrode of the wiring pattern PL901, the plate electrode PL91, and the capacitor electrode PC92 define the capacitor C4 in FIG. 20. That is, the plate electrode PL91 and the capacitor electrodes PC91 and PC93 define the resonator RC2 in FIG. 2.

The capacitor electrode PC92 partially overlaps the first electrode and the second electrode of the wiring pattern PL901 in plan view of the multilayer body 110 in the stacking direction. The first electrode and the second electrode of the wiring pattern PL901 and the capacitor electrode PC92 define the capacitor C5 in FIG. 2.

The capacitor electrode PC95 partially overlaps the first electrode of the wiring pattern PL902 and the plate electrode PL92 in plan view of the multilayer body 110 in the stacking direction. The first electrode of the wiring pattern PL902, the plate electrode PL92, and the capacitor electrode PC95 define the capacitor C53 in FIG. 20. The capacitor electrode PC97 partially overlaps the second electrode of the wiring pattern PL902 and the plate electrode PL92 in plan view of the multilayer body 110 in the stacking direction. The second electrode of the wiring pattern PL902, the plate electrode PL92, and the capacitor electrode PC97 define the capacitor C54 in FIG. 20. That is, the plate electrode PL92 and the capacitor electrodes PC95 and PC97 define the resonator RC5 in FIG. 2.

The capacitor electrode PC96 partially overlaps the first electrode and the second electrode of the wiring pattern PL902 in plan view of the multilayer body 110 in the stacking direction. The first electrode and the second electrode of the wiring pattern PL902 and the capacitor electrode PC96 define the capacitor C55 in FIG. 20.

A capacitor electrode PC98 that extends in the X-axis direction and that has a rectangular or substantially rectangular shape is disposed in the dielectric layer LY35. The capacitor electrode PC98 partially overlaps the plate electrode PL91 and the plate electrode PL92 in plan view of the multilayer body 110 in the stacking direction. The capacitor electrode PC98 and the plate electrodes PL91 and PL92 define the capacitor C40 in FIG. 20.

Also with the structure of the filter device 300A illustrated in FIG. 22, the equivalent circuit illustrated in FIG. 20 can be provided as described above.

According to the third example embodiment, the “filter circuit 200” and the “filter circuit 250” correspond to a “first filter circuit” and a “second filter circuit”. According to the third example embodiment, the “capacitor C40” corresponds to an “eleventh capacitor”. According to the third example embodiment, the “inductor L40” to the “inductor L43” correspond to a “sixth inductor” to a “ninth inductor”.

### Ninth Modification

In an example in FIG. 20, the resonator RC3 of the filter circuit 200 and the resonator RC4 of the filter circuit 250 are magnetically coupled with each other, and the resonator RC2 of the filter circuit 200 and the resonator RC5 of the filter circuit 250 are capacitively coupled with each other, but the magnetic coupling and the capacitive coupling may be reversed.

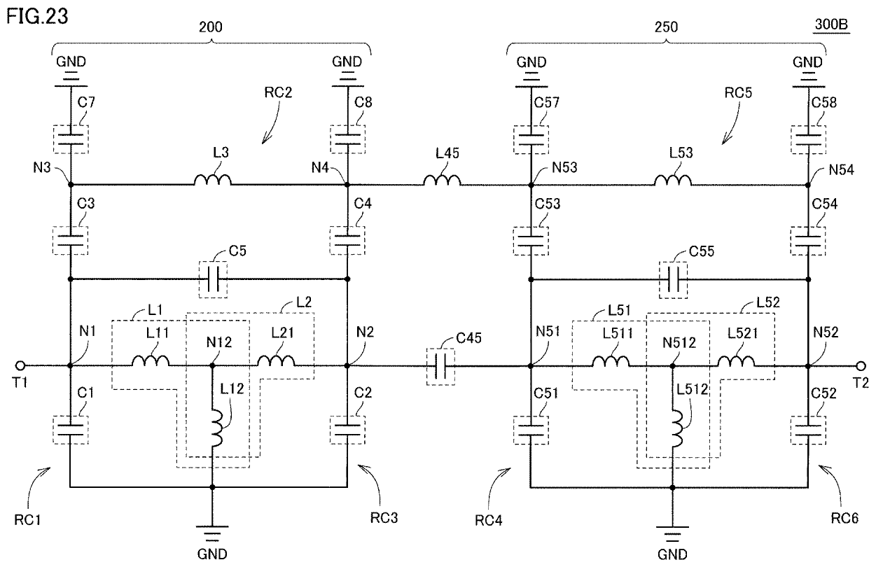

FIG. 23 is an equivalent circuit diagram of a filter device 300B according to a ninth modification of an example embodiment of the present invention. In the filter device 300B, a capacitor C45 is connected between the connection node N2 of the filter circuit 200 and the connection node N51 of the filter circuit 250, and an inductor L45 is connected between the connection node N4 of the filter circuit 200 and the connection node N53 of the filter circuit 250. That is, in the filter device 300B, RC3 and the resonator RC4 are capacitively coupled with each other, and the resonator RC2 and the resonator RC5 are magnetically coupled with each other.

Also in the filter device 300B, the filter circuit 200 and the filter circuit 250 are magnetically coupled with each other and capacitively coupled with each other, and the same or substantially the same advantageous effects as those of the filter device 300 can be achieved.

The “inductor L45” according to the ninth modification corresponds to a “tenth inductor”. The “capacitor C45” according to the ninth modification corresponds to a “twelfth capacitor”.

### [Aspect]

A person skilled in the art understands that the multiple example embodiments and modifications thereof described above are by way of example, and example embodiments of the present invention are described below.

A filter circuit according to an example embodiment of the present invention includes a first terminal, a second terminal, a ground terminal, a first resonator connected to the first terminal, a second resonator, and a third resonator connected to the second terminal. The second resonator is coupled with the first resonator and the second resonator. The first resonator and the third resonator are magnetically coupled with each other and capacitively coupled with each other. The first resonator includes a first inductor and a first capacitor connected in parallel between the first terminal and the ground terminal. The third resonator includes a second inductor and a second capacitor connected in parallel between the second terminal and the ground terminal. The second resonator includes a third inductor including a first end portion and a second end portion, a third capacitor including a first end connected to the first end portion of the third inductor, and a fourth capacitor including a first end connected to the second end portion of the third inductor.

A filter circuit according to an example embodiment of the present invention further includes a fifth capacitor that is connected between the first terminal and the second terminal.

In a filter circuit according to an example embodiment of the present invention, the first inductor and the second inductor have a portion in common.

A filter circuit according to an example embodiment of the present invention further includes a sixth capacitor connected between the first resonator and the ground terminal and between the third resonator and the ground terminal.

In a filter circuit according to an example embodiment of the present invention, the second resonator is magnetically coupled with the first resonator and the third resonator.

In a filter circuit according to an example embodiment of the present invention, the third inductor includes a fourth inductor and a fifth inductor connected in series between the third capacitor and the fourth capacitor. The first inductor is magnetically coupled with the fourth inductor. The second inductor is magnetically coupled with the fifth inductor.

In a filter circuit according to an example embodiment of the present invention, a second end of the third capacitor is connected to a second end of the fourth capacitor.

In a filter circuit according to an example embodiment of the present invention, the first end portion or the second end portion of the third inductor is connected to the ground terminal.

In a filter circuit according to an example embodiment of the present invention, a second end of the third capacitor and a second end of the fourth capacitor are connected to the ground terminal.

In a filter circuit according to an example embodiment of the present invention, the second resonator is capacitively coupled with the first resonator and the third resonator.

In a filter circuit according to an example embodiment of the present invention, a second end of the third capacitor is connected to the first terminal. A second end of the fourth capacitor is connected to the second terminal.

A filter circuit according to an example embodiment of the present invention further includes a seventh capacitor connected between the first end portion of the third inductor and the ground terminal and an eighth capacitor connected between the second end portion of the third inductor and the ground terminal.

In a filter circuit according to an example embodiment of the present invention, the first end of the fourth capacitor is connected to the second terminal. A second end of the third capacitor and a second end of the fourth capacitor are connected to the first terminal.

In a filter circuit according to an example embodiment of the present invention, the first end of the third capacitor is connected to the first terminal. A second end of the third capacitor and a second end of the fourth capacitor are connected to the second terminal.

A filter circuit according to an example embodiment of the present invention further includes an input terminal to receive a signal that is transmitted to the first terminal, an output terminal to output a signal from the second terminal, a ninth capacitor connected between the input terminal and the first terminal, and a tenth capacitor connected between the output terminal and the second terminal.

A filter device according to an example embodiment of the present invention includes an input terminal, an output terminal, a first filter circuit, and a second filter circuit magnetically coupled and capacitively coupled with the first filter circuit. The first filter circuit and the second filter circuit are configured as the filter circuit according to any example embodiment of the present invention. A first terminal of the first filter circuit is connected to the input terminal. A second terminal of the second filter circuit is connected to the output terminal.

A filter device according to an example embodiment of the present invention further includes an eleventh capacitor and a sixth inductor. The eleventh capacitor is connected to a second resonator in the first filter circuit and a second resonator in the second filter circuit. The sixth inductor is connected to a second terminal of the first filter circuit and a first terminal of the second filter circuit.

In a filter device according to an example embodiment of the present invention, the sixth inductor includes a seventh inductor including a first end connected to the second terminal of the first filter circuit, an eighth inductor connected between a second end of the seventh inductor and the first terminal of the second filter circuit, and a ninth inductor connected between the second end of the seventh inductor and the ground terminal.

A filter device according to an example embodiment of the present invention further includes a tenth inductor and a twelfth capacitor. The tenth inductor is connected to a second resonator in the first filter circuit and a second resonator in the second filter circuit, and the twelfth capacitor is connected to a second terminal of the first filter circuit and a first terminal of the second filter circuit.

A filter device according to an example embodiment of the present invention includes a multilayer body, an input terminal, an output terminal, a ground electrode connected to a ground terminal, first to seventh capacitor electrodes, first to third plate electrodes, and first to third vias. The multilayer body includes multiple stacked dielectric layers and a first surface and a second surface that face away from each other. The input terminal, the output terminal, and the ground terminal are provided in or on the second surface of the multilayer body. The first capacitor electrode is connected to the input terminal and at least partially overlaps the ground electrode in plan view in a normal direction to the first surface. The first plate electrode is connected to the first capacitor electrode. The second capacitor electrode is connected to the output terminal and at least partially overlaps the ground electrode in plan view in the normal direction to the first surface. The second plate electrode is connected to the second capacitor electrode and is provided in a same dielectric layer as the first plate electrode. The first via is connected to the first plate electrode and the second plate electrode and is connected to the ground electrode. The third plate electrode is provided in the same dielectric layer as the first plate electrode and the second plate electrode and is magnetically coupled with the first plate electrode and the second plate electrode. The second via and the third via are connected to the third plate electrode. The third capacitor electrode is connected to the second via and at least partially overlaps the ground electrode in plan view in the normal direction to the first surface. The fourth capacitor electrode is connected to the third via and at least partially overlaps the ground electrode in plan view in the normal direction to the first surface. The fifth capacitor electrode at least partially overlaps the first capacitor electrode and the second capacitor electrode in plan view in the normal direction to the first surface. The sixth capacitor electrode at least partially overlaps the first capacitor electrode and the third capacitor electrode in plan view in the normal direction to the first surface. The seventh capacitor electrode at least partially overlaps the second capacitor electrode and the fourth capacitor electrode in plan view in the normal direction to the first surface.

A filter device according to an example embodiment of the present invention includes a multilayer body, an input terminal, an output terminal, a ground terminal, a ground electrode connected to the ground terminal, and first to sixth electrodes. The multilayer body includes multiple stacked dielectric layers and a first surface and a second surface that face away from each other. The input terminal, the output terminal, and the ground terminal are provided in or on the second surface of the multilayer body. The first electrode at least partially overlaps the ground electrode in plan view in a normal direction to the first surface and is connected to the input terminal. The second electrode at least partially overlaps the ground electrode in plan view in the normal direction to the first surface, is provided in a same dielectric layer as the first electrode, and is connected to the output terminal. The third electrode is connected to the first electrode and the second electrode. The fourth electrode is adjacent to the first electrode and the second electrode and at least partially overlaps the ground electrode in plan view in the normal direction to the first surface. The fifth electrode at least partially overlaps the first electrode and the third electrode in plan view in the normal direction to the first surface. The sixth electrode at least partially overlaps the second electrode and the third electrode in plan view in the normal direction to the first surface. The first electrode and the second electrode are spaced apart from each other, face each other, and include a capacitively coupled region.

In a filter device according to an example embodiment of the present invention, the fourth electrode is connected to the ground electrode.

In a filter device according to an example embodiment of the present invention, the fourth electrode is not connected to the ground electrode. The filter device further includes a seventh electrode connected to the ground electrode. The seventh electrode at least partially overlaps the fourth electrode in plan view in the normal direction to the first surface.

In a filter device according to an example embodiment of the present invention, the multilayer body has a rectangular or substantially rectangular shape including a first side and a second side adjacent to each other in plan view in the normal direction to the first surface. Elements provided in or on the multilayer body are line symmetric with respect to an imaginary line passing through a center of the first side and being parallel or substantially parallel with the second side in plan view in the normal direction to the first surface.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter circuit comprising:
a first terminal;
a second terminal;
a ground terminal;
a first resonator connected to the first terminal;
a second resonator; and
a third resonator connected to the second terminal; wherein
the second resonator is coupled with the first resonator and the third resonator;
the first resonator and the third resonator are magnetically coupled with each other and capacitively coupled with each other;
the first resonator includes a first inductor and a first capacitor connected in parallel between the first terminal and the ground terminal;
the third resonator includes a second inductor and a second capacitor connected in parallel between the second terminal and the ground terminal; and
the second resonator includes:
a third inductor including a first end portion and a second end portion;
a third capacitor including a first end connected to the first end portion of the third inductor; and
a fourth capacitor including a first end connected to the second end portion of the third inductor.

2. The filter circuit according to claim 1, further comprising a fifth capacitor connected between the first terminal and the second terminal.

3. The filter circuit according to claim 1, wherein the first inductor and the second inductor include a common portion.

4. The filter circuit according to claim 1, further comprising a sixth capacitor connected between the first resonator and the ground terminal and between the third resonator and the ground terminal.

5. The filter circuit according to claim 1, wherein the second resonator is magnetically coupled with the first resonator and the third resonator.

6. The filter circuit according to claim 5, wherein
the third inductor includes a fourth inductor and a fifth inductor connected in series between the third capacitor and the fourth capacitor;
the first inductor is magnetically coupled with the fourth inductor; and
the second inductor is magnetically coupled with the fifth inductor.

7. The filter circuit according to claim 5, wherein a second end of the third capacitor is connected to a second end of the fourth capacitor.

8. The filter circuit according to claim 7, wherein the first end portion or the second end portion of the third inductor is connected to the ground terminal.

9. The filter circuit according to claim 5, wherein a second end of the third capacitor and a second end of the fourth capacitor are connected to the ground terminal.

10. The filter circuit according to claim 1, wherein the second resonator is capacitively coupled with the first resonator and the third resonator.

11. The filter circuit according to claim 10, wherein
a second end of the third capacitor is connected to the first terminal; and
a second end of the fourth capacitor is connected to the second terminal.

12. The filter circuit according to claim 11, further comprising a seventh capacitor connected between the first end portion of the third inductor and the ground terminal, and an eighth capacitor connected between the second end portion of the third inductor and the ground terminal.

13. The filter circuit according to claim 10, wherein
the first end of the fourth capacitor is connected to the second terminal; and
a second end of the third capacitor and a second end of the fourth capacitor are connected to the first terminal.

14. The filter circuit according to claim 10, wherein
the first end of the third capacitor is connected to the first terminal; and
a second end of the third capacitor and a second end of the fourth capacitor are connected to the second terminal.

15. The filter circuit according to claim 1, further comprising:
an input terminal to receive a signal transmitted to the first terminal;
an output terminal to output a signal from the second terminal;
a ninth capacitor connected between the input terminal and the first terminal; and
a tenth capacitor connected between the output terminal and the second terminal.

16. A filter device comprising:
an input terminal;
an output terminal;
a first filter circuit; and
a second filter circuit magnetically coupled and capacitively coupled with the first filter circuit; wherein
the first filter circuit and the second filter circuit are each defined by the filter circuit according to claim 1;
a first terminal of the first filter circuit is connected to the input terminal; and
a second terminal of the second filter circuit is connected to the output terminal.

17. The filter device according to claim 16, further comprising:
an eleventh capacitor connected to a second resonator in the first filter circuit and a second resonator in the second filter circuit; and
a sixth inductor connected to a second terminal of the first filter circuit and a first terminal of the second filter circuit.

18. The filter device according to claim 17, wherein the sixth inductor includes:
a seventh inductor including a first end connected to the second terminal of the first filter circuit;
an eighth inductor connected between a second end of the seventh inductor and the first terminal of the second filter circuit; and
a ninth inductor connected between the second end of the seventh inductor and the ground terminal.

19. The filter device according to claim 16, further comprising:
a tenth inductor connected to a second resonator in the first filter circuit and a second resonator in the second filter circuit; and
a twelfth capacitor connected to a second terminal of the first filter circuit and a first terminal of the second filter circuit.

20. A filter device comprising:
a multilayer body including multiple stacked dielectric layers, and a first surface and a second surface facing away from each other;
an input terminal, an output terminal, and a ground terminal in or on the second surface of the multilayer body;
a ground electrode connected to the ground terminal;
a first capacitor electrode connected to the input terminal and at least partially overlapping the ground electrode in plan view in a normal direction to the first surface;
a first plate electrode connected to the first capacitor electrode;
a second capacitor electrode connected to the output terminal and at least partially overlapping the ground electrode in plan view in the normal direction to the first surface;
a second plate electrode connected to the second capacitor electrode and provided in a same dielectric layer as the first plate electrode;
a first via connected to the first plate electrode and the second plate electrode and connected to the ground electrode;
a third plate electrode provided in the same dielectric layer as the first plate electrode and the second plate electrode and being magnetically coupled with the first plate electrode and the second plate electrode;
a second via and a third via connected to the third plate electrode;
a third capacitor electrode connected to the second via and at least partially overlapping the ground electrode in plan view in the normal direction to the first surface;
a fourth capacitor electrode connected to the third via and at least partially overlapping the ground electrode in plan view in the normal direction to the first surface;
a fifth capacitor electrode at least partially overlapping the first capacitor electrode and the second capacitor electrode in plan view in the normal direction to the first surface;
a sixth capacitor electrode at least partially overlapping the first capacitor electrode and the third capacitor electrode in plan view in the normal direction to the first surface; and
a seventh capacitor electrode at least partially overlapping the second capacitor electrode and the fourth capacitor electrode in plan view in the normal direction to the first surface.

21. A filter device comprising:
a multilayer body including multiple stacked dielectric layers and a first surface and a second surface facing away from each other;
an input terminal, an output terminal, and a ground terminal in or on the second surface of the multilayer body;
a ground electrode connected to the ground terminal;
a first electrode at least partially overlapping the ground electrode in plan view in a normal direction to the first surface and that is connected to the input terminal;
a second electrode at least partially overlapping the ground electrode in plan view in the normal direction to the first surface, provided in a same dielectric layer as the first electrode, and connected to the output terminal;
a third electrode connected to the first electrode and the second electrode;
a fourth electrode adjacent to the first electrode and the second electrode and at least partially overlapping the ground electrode in plan view in the normal direction to the first surface;
a fifth electrode at least partially overlapping the first electrode and the third electrode in plan view in the normal direction to the first surface; and
a sixth electrode at least partially overlapping the second electrode and the third electrode in plan view in the normal direction to the first surface; wherein
the first electrode and the second electrode are spaced apart from each other, face each other, and include a capacitively coupled region.

22. The filter device according to claim 21, wherein the fourth electrode is connected to the ground electrode.

23. The filter device according to claim 21, further comprising:
a seventh electrode connected to the ground electrode; wherein
the fourth electrode is not connected to the ground electrode; and
the seventh electrode at least partially overlaps the fourth electrode in plan view in the normal direction to the first surface.

24. The filter device according to claim 20, wherein
the multilayer body has a rectangular or substantially rectangular shape including a first side and a second side adjacent to each other in plan view in the normal direction to the first surface; and
elements in or on the multilayer body are line symmetric with respect to an imaginary line passing through a center of the first side and being parallel or substantially parallel with the second side in plan view in the normal direction to the first surface.
